(19) United States
(12) Patent Application Publication
(10) Pub. No.: US 2024/0324413 A1
(43) Pub. Date: Sep. 26, 2024

(54) DISPLAY PANEL

(71) Applicant: Samsung Display Co., Ltd., Yongin-Si (KR)

(72) Inventors: Junhyeong Park, Yongin-si (KR); Kyungmin Kim, Yongin-si (KR); Myunghee Han, Yongin-si (KR); Jiyeon Seo, Yongin-si (KR)

(21) Appl. No.: 18/440,972

(22) Filed: Feb. 14, 2024

(30) Foreign Application Priority Data
Mar. 24, 2023 (KR) 10-2023-0038977
Jun. 7, 2023 (KR) 10-2023-0073142

(51) Int. Cl. H10K 59/80

(52) U.S. Cl. CPC H10K 59/8731

(57) ABSTRACT

A display panel is disclosed that includes a substrate including a display area and a peripheral area around the display area, a display element located in the display area, a thin-film encapsulation layer covering the display area, and including a first inorganic encapsulation layer, an organic encapsulation layer, and a second inorganic encapsulation layer, and a plurality of grooves located in the peripheral area to be adjacent to an end of the substrate, wherein the end of the substrate is recessed away from the display element, and a side surface of the end of the substrate is one plane.

### CROSS-REFERENCE TO RELATED APPLICATION

This application is based on and claims priority under 35 U.S.C. § 119 to Korean Patent Application Nos. 10-2023-0038977 and 10-2023-0073142, respectively filed on Mar. 24, 2023 and Jun. 7, 2023, in the Korean Intellectual Property Office, the disclosures of which are incorporated by reference herein in their entirety.

### BACKGROUND

### 1. Field

One or more embodiments relate to a display panel.

### 2. Description of the Related Art

Mobility-based electronic devices are widely used. Recently, tablet personal computers (PCs), in addition to small electronic devices such as mobile phones, have become widely used as mobile electronic devices.

A mobile electronic device includes a display panel for providing visual information such as an image or a video to a user, in order to support various functions. Recently, as other components for driving a display panel have been miniaturized, the proportion of the display panel in an electronic device has gradually increased, and a structure that is bendable at a certain angle from a flat state has been developed.

### SUMMARY

A display panel includes a display area and a peripheral area. Recently, many efforts have been made to display an image provided by a display area on the entire display apparatus by increasing the area of the display area and to reduce the size of the display apparatus by reducing the area of a peripheral area. One or more embodiments may include a display panel and a display apparatus in which a display area is increased and a peripheral area is decreased relative to an overall area of the display panel.

Additional aspects will be set forth in part in the description which follows and, in part, will be apparent from the description, or may be learned by practice of the presented embodiments.

According to one or more embodiments, a display panel includes a substrate including a display area and a peripheral area around the display area, a display element located in the display area, a thin-film encapsulation layer covering the display area, and including a first inorganic encapsulation layer, an organic encapsulation layer, and a second inorganic encapsulation layer, and a plurality of grooves located in the peripheral area to be adjacent to an end of the substrate, wherein the end of the substrate is recessed away from the display element, and a side surface of the end of the substrate is one plane.

The display panel may further include an inorganic insulating layer located between the substrate and the display element, and an inorganic layer located on the substrate in the peripheral area.

At least one of a barrier layer of the substrate, the inorganic insulating layer, the organic layer, the first inorganic encapsulation layer, and the second inorganic encapsulation layer may be located between the plurality of grooves.

The substrate may include a first base layer, a second base layer located between the first base layer and the display element, and a barrier layer located between the first base layer and the second base layer.

Each of the plurality of grooves may be located in the second base layer.

The display panel may further include a terminal unit located on the substrate, and an edge inorganic layer located on an end portion of the substrate adjacent to the terminal unit, wherein a side surface of the edge inorganic layer located on the end portion of the substrate adjacent to the terminal unit, and a side surface of the substrate form one plane.

The display pane may further include an inorganic insulating layer located between the substrate and the display element, wherein the edge inorganic layer includes at least one of a barrier layer of the substrate, the inorganic insulating layer, the inorganic layer, the first inorganic encapsulation layer, and the second inorganic encapsulation layer.

According to one or more embodiments, a display panel includes a substrate including a display area and a peripheral area around the display area, a display element located in the display area, a thin-film encapsulation layer covering the display area, and including a first inorganic encapsulation layer, an organic encapsulation layer, and a second inorganic encapsulation layer, a plurality of grooves located in the peripheral area to be adjacent to an end of the substrate, a terminal unit located on the substrate, and a first edge inorganic layer located on a protruding portion of the substrate located outside the plurality of grooves, wherein, in a plan view, a portion of the first edge inorganic layer close to the terminal unit is open, and a side surface of the end of the substrate and a side surface of an end of the first edge inorganic layer are on a same plane.

The display panel may further include an inorganic insulating layer located between the substrate and the display element, and an inorganic layer located on the substrate between the first edge inorganic layer and the inorganic insulating layer.

The first edge inorganic layer may include at least one of a barrier layer of the substrate, the inorganic insulating layer, the inorganic layer, the first inorganic encapsulation layer, and the second inorganic encapsulation layer.

The substrate may include a first base layer, a second base layer located between the first base layer and the display element, and a barrier layer located between the first base layer and the second base layer.

Each of the plurality of grooves may be located on the second base layer.

The display panel may further include a second edge inorganic layer located on an end portion of the substrate adjacent to the terminal unit, wherein a side surface of the second edge inorganic layer located on the end portion of the substrate adjacent to the terminal unit and a side surface of the substrate are on a same plane.

The display panel may further include an inorganic insulating layer located between the substrate and the display element, wherein the second edge inorganic layer includes at least one of a part of the substrate and the inorganic insulating layer.

According to one or more embodiments, a display panel includes a substrate including a display area and a peripheral area around the display area, a display element located in the display area, and a thin-film encapsulation layer covering the display area, and including a first inorganic encapsulation layer, an organic encapsulation layer, and a second inorganic encapsulation layer, wherein the substrate includes a first base layer, a second base layer located between the first base layer and the display element, and a first barrier layer located between the first base layer and the second base layer.

An end of the first barrier layer may protrude from at least one of a side surface of the first base layer and a side surface of the second base layer.

The side surface of the first base layer and the side surface of the second base layer may be on a same plane.

At least one of the first inorganic encapsulation layer and the second inorganic encapsulation layer may surround a side surface of the substrate.

The display panel may further include a terminal unit located on the substrate, and an edge inorganic layer located on an end portion of the substrate adjacent to the terminal unit, wherein a side surface of the edge inorganic layer located on the end portion of the substrate adjacent to the terminal unit and a side surface of the substrate form one plane.

The display panel may further include an inorganic insulating layer located between the substrate and the display element, wherein the edge inorganic layer includes at least one of a part of the substrate and the inorganic insulating layer.

The display panel may further include an inorganic layer located between an end of the substrate and the display element, wherein an end of the inorganic layer located on the end of the substrate protrudes from at least one of a side surface of the first base layer and a side surface of the second base layer.

According to one or more embodiments, a display apparatus includes a cover window including a flat portion and a curved portion bent at a corner of the flat portion, and the display panel located on one surface of the cover window.

Other aspects, features, and advantages of the disclosure will become more apparent from the drawings, the claims, and the detailed description.

### BRIEF DESCRIPTION OF THE DRAWINGS

The above and other aspects, features, and advantages of certain embodiments will be more apparent from the following description taken in conjunction with the accompanying drawings, in which:

FIG. 1 is a perspective view schematically illustrating a display apparatus, according to an embodiment;

FIG. 2 is an exploded perspective view schematically illustrating a display panel and a cover window of a display apparatus, according to an embodiment;

FIG. 3 is a perspective view schematically illustrating a display panel of a display apparatus, according to an embodiment;

FIG. 4 is a cross-sectional view taken along a line A-A′ of FIG. 1;

FIG. 5 is a schematic plan view illustrating a state where a display panel that may be included in the display apparatus of FIG. 1 is unfolded, according to an embodiment;

FIG. 6 is an enlarged view illustrating a portion B of FIG. 5;

FIG. 7 is a cross-sectional view schematically illustrating a part of the display panel, taken along a line C-C′ of FIG. 6, according to an embodiment;

FIG. 8 is an equivalent circuit diagram illustrating a pixel circuit that may be applied to a display panel, according to an embodiment;

FIG. 9 is a cross-sectional view schematically illustrating a portion of a display panel, according to an embodiment;

FIG. 10 is a plan view illustrating an arrangement of a mother substrate and a display panel for manufacturing a display panel, according to an embodiment;

FIG. 11A is a cross-sectional view schematically illustrating a part of the display panel, taken along a line D-D′ of FIG. 10, according to an embodiment;

FIG. 11B is a cross-sectional view schematically illustrating a part of the display panel, taken along the line D-D′ of FIG. 10, according to another embodiment;

FIG. 12 is a cross-sectional view schematically illustrating a part of the display panel, taken along a line E-E′ of FIG. 10, according to an embodiment;

FIG. 13 is a cross-sectional view schematically illustrating a part of the display panel, taken along the line D-D′ of FIG. 10, according to another embodiment;

FIG. 14 is a cross-sectional view schematically illustrating a part of a method of manufacturing the display panel of FIG. 13;

FIG. 15 is a schematic plan view illustrating a state where a part of a display panel is unfolded, according to another embodiment; and

FIG. 16 is a schematic cross-sectional view taken along a line E-E′ of FIG. 15.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description.

As used herein, the word “or” means logical “or” so that, unless the context indicates otherwise, the expression “A, B, or C” means “A and B and C,” “A and B but not C,” “A and C but not B,” “B and C but not A,” “A but not B and not C,” “B but not A and not C,” and “C but not A and not B.” Throughout the disclosure, the expression “at least one of a, b or c” indicates only a, only b, only c, both a and b, both a and c, both b and c, all of a, b, and c, or variations thereof.

As the disclosure allows for various changes and numerous embodiments, certain embodiments will be illustrated in the drawings and described in the detailed description. Effects and features of the disclosure, and methods for achieving them will be clarified with reference to embodiments described below in detail with reference to the drawings. However, the disclosure is not limited to the following embodiments and may be embodied in various forms.

Hereinafter, embodiments will be described in detail with reference to the accompanying drawings, wherein the same or corresponding elements are denoted by the same reference numerals throughout and a repeated description thereof is omitted.

Although the terms “first,” “second,” etc. may be used to describe various elements, these elements should not be limited by these terms. These terms are only used to distinguish one element from another.

As used herein, the singular forms “a,” “an,” and “the” when used as a referent are intended to include the plural forms as well, unless the context clearly indicates otherwise.

It will be understood that the terms “comprising,” “including,” and “having” (as well as their variants such as “comprises”) are intended to indicate the existence of the features or elements described in the specification, and are not intended to preclude the possibility that one or more other features or elements may exist or may be added.

It will be further understood that, when a layer, region, or component is referred to as being “on” another layer, region, or component, it may be directly on the other layer, region, or component, or may be indirectly on the other layer, region, or component with intervening layers, regions, or components therebetween.

Sizes of components in the drawings may be exaggerated or reduced for convenience of explanation. For example, because sizes and thicknesses of elements in the drawings are arbitrarily illustrated for convenience of explanation, the disclosure is not limited thereto.

In the following embodiments, the x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

When a certain embodiment may be implemented differently, a specific process order may be different from the described order. For example, two consecutively described processes may be performed substantially at the same time or may be performed in an order opposite to the described order.

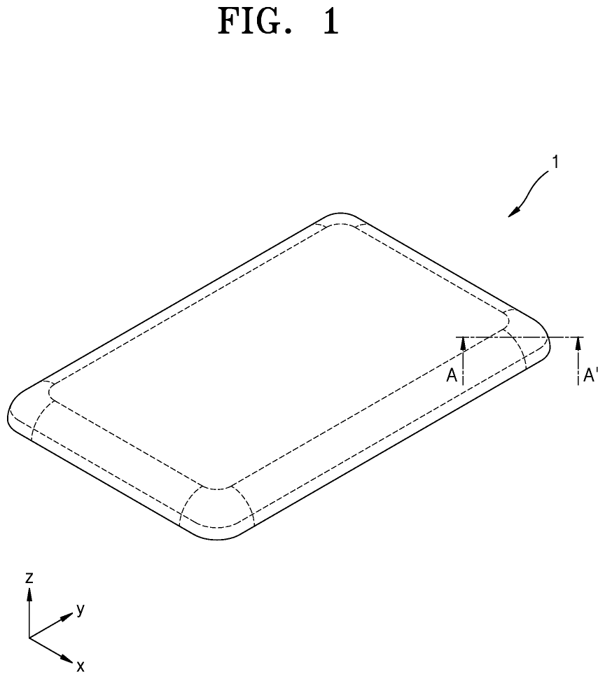

FIG. 1 is a perspective view schematically illustrating a display apparatus, according to an embodiment.

Referring to FIG. 1, a display apparatus 1 according to an embodiment is a device for displaying a moving image or a still image, and may be a portable electronic device such as a mobile phone, a smartphone, a tablet personal computer (PC), a mobile communication terminal, an electronic organizer, an electronic book, a portable multimedia player (PMP), a navigation device, or a ultra-mobile PC (UMPC). Also, the display apparatus 1 may be an electronic device that provides a display screen, such as a television, a laptop computer, a monitor, an advertisement board, or an Internet of Things (IoT) device. Alternatively, the display apparatus 1 may be a wearable device such as a smart watch, a watch phone, a glasses-type display, or a head-mounted display (HMD).

In an embodiment, the display apparatus 1 may have a quadrangular shape in a plan view. Alternatively, the display apparatus 1 may have any of various shapes such as a polygonal shape (e.g., a triangular shape or a quadrangular shape), a circular shape, or an elliptical shape. In an embodiment, when the display apparatus 1 has a polygonal shape in a plan view, corners of the polygonal shape may be rounded. For convenience of explanation, the following will be described assuming that the display apparatus 1 has a quadrangular shape with rounded corners in a plan view.

The display apparatus 1 may have a short side in a first direction (e.g., an x direction or a −x direction) and a long side in a second direction (e.g., a y direction or a −y direction). In another embodiment, a length of a side of the display apparatus 1 in the first direction (e.g., the x direction or the −x direction) and a length of a side of the display apparatus 1 in the second direction (e.g., the y direction or the −y direction) may be the same. In another embodiment, the display apparatus 1 may have a long side in the first direction (e.g., the x direction or the −x direction) and a short side in the second direction (e.g., the y direction or the −y direction). Each corner where a short side in the first direction (e.g., the x direction or the −x direction) and a long side in the second direction (e.g., the y direction or the −y direction) meet each other may be rounded to have a certain curvature.

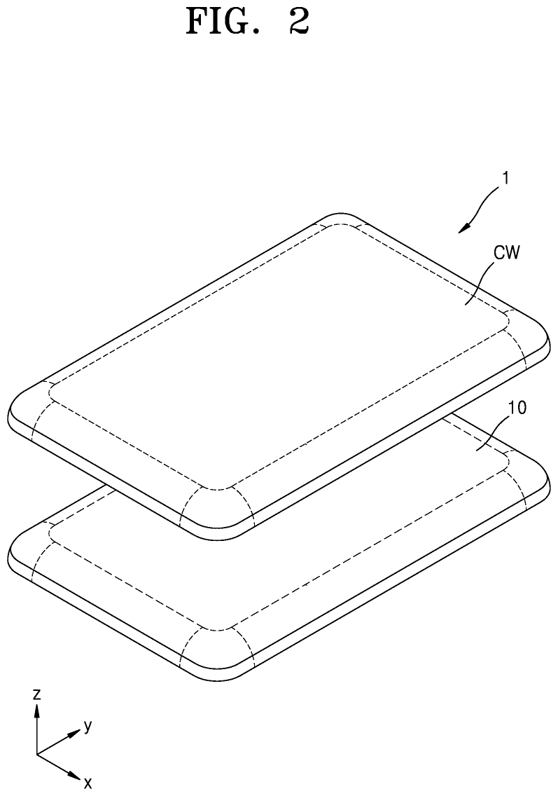

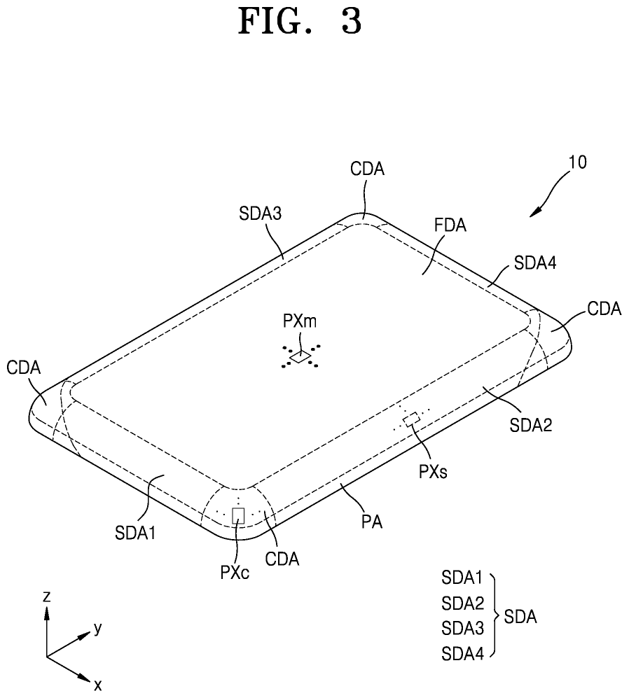

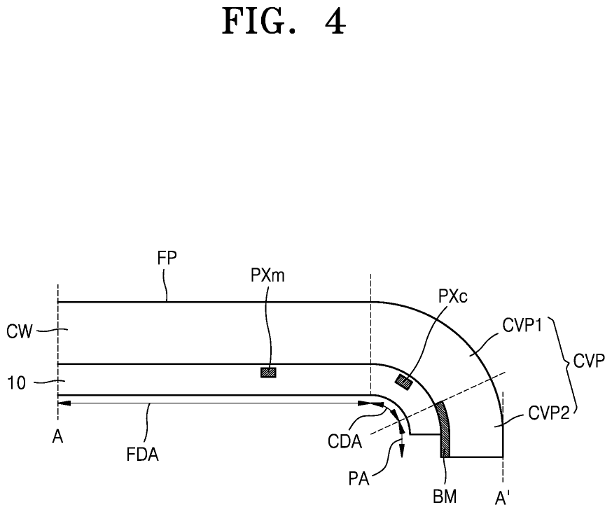

FIG. 2 is an exploded perspective view schematically illustrating a display panel and a cover window of a display apparatus, according to an embodiment; FIG. 3 is a perspective view schematically illustrating a display panel of a display apparatus, according to an embodiment. FIG. 4 is a cross-sectional view taken along line A-A′ of FIG. 1.

Referring to FIGS. 2 to 4, the display apparatus 1 may include a display panel 10 and a cover window CW located on the display panel 10.

The display panel 10 may include a front display area FDA, a side display area SDA, and a corner display area CDA as a display area. The display apparatus 1 may include a peripheral area PA surrounding the display area.

The front display area FDA may be an area located on a front surface of the display panel 10 and formed flat without being bent. The front display area FDA may have a largest proportion in the display area of the display panel 10, and thus, may provide most of images. That is, the front display area FDA may be a main display area. The front display area FDA may have a short side in the x direction and a long side in the y direction, and each corner where the short side and the long side meet each other may have a round rectangular shape.

At least a part of the side display area SDA may be bent to have a curved surface, and the side display area SDA may extend outward from each side of the front display area FDA. The side display area SDA may include a first side display area SDA1, a second side display area SDA2, a third side display area SDA3, and a fourth side display area SDA4. In some embodiments, at least one of the first side display area SDA1, the second side display area SDA2, the third side display area SDA3, and the fourth side display area SDA4 may be omitted.

The first side display area SDA1 may be an area extending from a first side of the front display area FDA and bent with a certain curvature. The first side display area SDA1 may extend from a lower side of the front display area FDA. The first side display area SDA1 may be an area located on a bottom surface of the display panel 10.

The second side display area SDA2 may be an area extending from a second side of the front display area FDA and bent with a certain curvature. The second side display area SDA2 may extend from a right side of the front display area FDA. The second side display area SDA2 may be an area located on a right surface of the display panel 10.

The third side display area SDA3 may be an area extending from a third side of the front display area FDA and bent with a certain curvature. The third side display area SDA3 may extend from a left side of the front display area FDA. The third side display area SDA3 may be an area located on a left surface of the display panel 10.

The fourth side display area SDA4 may be an area extending from a fourth side of the front display area FDA and bent with a certain curvature. The fourth side display area SDA4 may extend from an upper side of the front display area FDA. The fourth side display area SDA4 may be an area located on an upper surface of the display panel 10.

Each of the first to fourth side display areas SDA1, SDA2, SDA3, and SDA4 may include a curved surface bent with a certain curvature. For example, each of the first side display area SDA1 and the fourth side display area SDA4 may include a curved surface bent about a bending axis extending in the x direction, and each of the second side display area SDA2 and the third side display area SDA3 may include a curved surface bent about a bending axis extending in the y direction. Curvatures of the first to fourth side display areas SDA1, SDA2, SDA3, and SDA4 may be the same or different from each other.

The corner display area CDA may be an area extending from a corner of the front display area FDA and bent with a certain curvature. The corner display area CDA may be located between the first to fourth side display areas SDA1 to SDA4. For example, the corner display area CDA may be located between the first side display area SDA1 and the second side display area SDA2, between the first side display area SDA1 and the third side display area SDA3, between the second side display area SDA2 and the fourth side display area SDA4, and between the third side display area SDA3 and the fourth side display area SDA4.

Because the corner display area CDA is located between adjacent side display areas SDA having curved surfaces bent in different directions, the corner display area CDA may include a curved surface formed by continuously connecting curved surfaces bent in multiple directions. Also, when curvatures of adjacent side display areas SDA are different from each other, a curvature of the corner display area CDA may gradually change according to an edge of the display apparatus 1. For example, when a curvature of the first side display area SDA1 and a curvature of the second side display area SDA2 are different from each other, the corner display area CDA between the first side display area SDA1 and the second side display area SDA2 may have a curvature that gradually changes according to a position.

The display panel 10 may provide an image by using main pixels PXm located in the front display area FDA, side pixels PXs located in the side display area SDA, and corner pixels PXc located in the corner display area CDA. Because the display panel 10 provides an image in the side display area SDA and the corner display area CDA in addition to the front display area FDA, the proportion of the display area in the display apparatus 1 may increase. That is, in the display apparatus 1 having the same size, the area of the peripheral area PA may decrease and the area of the display area may increase.

The peripheral area PA may entirely or partially surround outer portions of the side display area SDA and the corner display area CDA. The peripheral area PA is an area where an image is not provided, and various wirings and driving circuits may be located in the peripheral area PA. A shielding layer such as a light-blocking member may be provided in the peripheral area PA so that members located in the peripheral area PA are not visually recognized.

Referring to FIG. 4, the cover window CW may be located on a front surface of the display panel 10. The ‘front surface’ of the display panel 10 may be defined as a surface facing a direction in which the display panel 10 provides an image.

The cover window CW may cover and protect the display panel 10. The cover window CW may have a high transmittance to transmit light emitted from the display panel 10, and may have a small thickness to minimize a weight of the display apparatus 1. Also, the cover window CW may have high strength and high hardness to protect the display panel 10 from external impact.

The cover window CW may be formed of a transparent material. The cover window CW may include, for example, glass or plastic. When the cover window CW includes plastic, the cover window CW may be flexible. For example, the cover window CW may be formed of ultra-thin glass (UTG®) whose strength is enhanced by using a method such as chemical strengthening or thermal strengthening. In another embodiment, the cover window CW may be formed of ultra-thin glass (UTG®) and colorless polyimide (CPI). In an embodiment, the cover window CW may have a structure in which a flexible polymer layer is located on a surface of a glass substrate, or may include only a polymer layer.

The cover window CW may include a flat portion FP corresponding to the front display area FDA of the display panel 10 and a curved portion CVP corresponding to the side display area SDA and the corner display area CDA.

The flat portion FP of the cover window CW may be a flat surface and may overlap the front display area FDA of the display panel 10. The curved portion CVP of the cover window CW may be a curved surface, and in this case, the curved portion CVP may have a constant curvature or a changing curvature. The curved portion CVP may include a first curved portion CVP1 and a second curved portion CVP2. The first curved portion CVP1 may overlap the side display area SDA and the corner display area CDA of the display panel 10. The second curved portion CVP2 may overlap the peripheral area PA of the display panel 10. The first curved portion CVP1 may be located between the flat portion FP and the second curved portion CVP2.

A light-blocking member BM may be located on a part of the second curved portion CVP2 of the cover window CW. The light-blocking member BM for covering a lower structure located under the light-blocking member BM may overlap the peripheral area PA of the display panel 10. The light-blocking member BM may include a light-blocking material. The light-blocking member BM may be formed of a resin including carbon black, carbon nanotubes, and a black dyc. Alternatively, the light-blocking member BM may be formed of nickel, aluminum, molybdenum, or an alloy thereof. The light-blocking member BM may be applied by inkjet or attached as a film type.

The display panel 10 may be located under the cover window CW. The cover window CW and the display panel 10 may be coupled to each other through an adhesive member (not shown). The adhesive member may be an optically clear adhesive (OCA) film or an optically clear resin (OCR).

The display panel 10 may provide an image by using the main pixels PXm located in the front display area FDA and the corner pixels PXc located in the corner display area CDA. A lower protective film (not shown) for protecting the display panel 10 may be further located under the display panel 10.

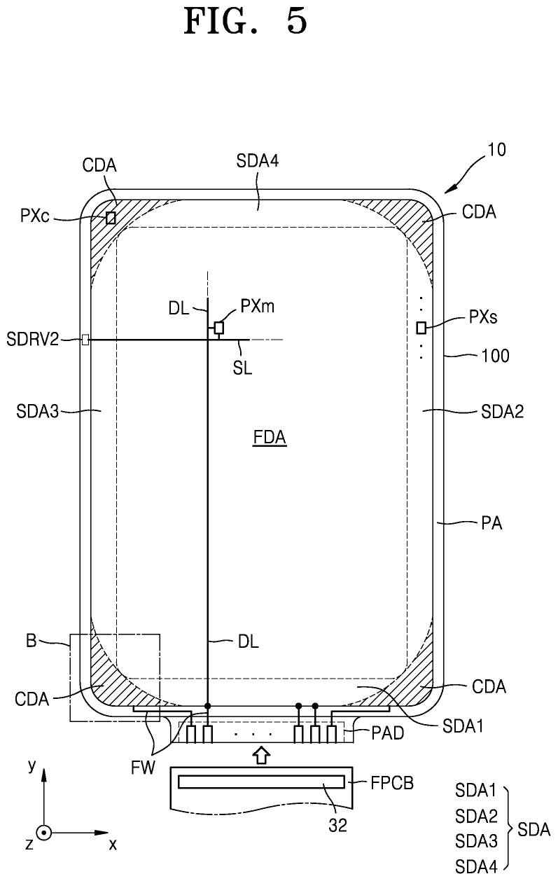

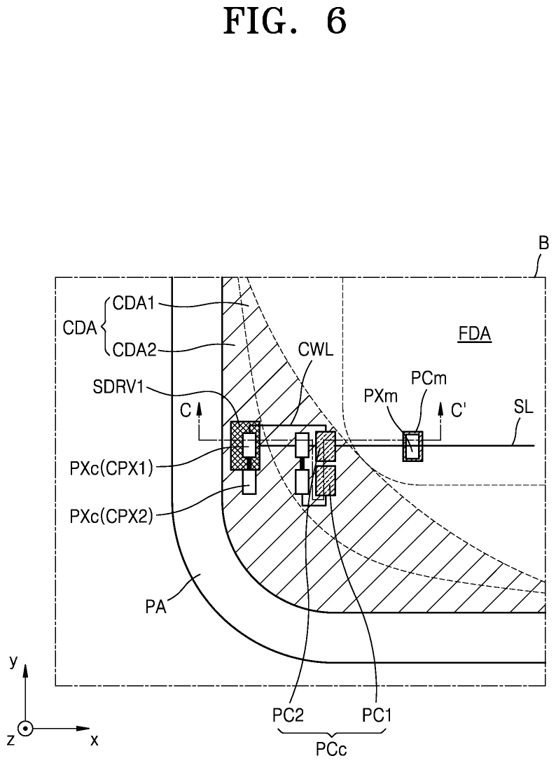

FIG. 5 is a schematic plan view illustrating a state where a display panel that may be included in the display apparatus of FIG. 1 is unfolded, according to an embodiment. FIG. 6 is an enlarged view illustrating a portion B of FIG. 5.

Referring to FIGS. 5 and 6, various elements constituting the display panel 10 are located on a substrate 100. The substrate 100 includes the front display area FDA, the side display area SDA, the corner display area CDA, and the peripheral area PA.

A plurality of main pixels PXm may be located in the front display area FDA, and a main image may be displayed by the plurality of main pixels PXm. The main pixel PXm may include a set of sub-pixels. Each sub-pixel may emit red light, green light, blue light, or white light.

The side display area SDA may be located the upper, lower, left, and right sides of the front display area FDA. A plurality of side pixels PXs may be located in the side display area SDA, and a side image may be displayed by the plurality of side pixels PXs. The side image may form one whole image together with the main image, or may be an image independent of the main image.

The corner display area CDA may extend from a corner of the front display area FDA. The corner display area CDA may be located between two side display areas SDA. A plurality of corner pixels PXc may be located in the corner display area CDA, and a corner image may be displayed by the plurality of corner pixels PXc. The corner image may form one whole image together with the main image and the side image, or may be an image independent of the main image.

The corner display area CDA may include a first corner display area CDA1 and a second corner display area CDA2. The second corner display area CDA2 is an area extending from the first corner display area CDA1, and the second corner display area CDA2 may be located on an edge of the substrate 100 more than the first corner display CDA1. The first corner display area CDA1 may be located between the second corner display area CDA2 and the front display area FDA.

A driving circuit SDRV1 in addition to the corner pixels PXc may be located in the second corner display area CDA2. The driving circuit SDRV1 may provide a scan signal for driving the main pixels PXm and the corner pixels PXc located in the front display area FDA and the corner display area CDA. In some embodiments, the driving circuit SDRV1 may be simultaneously connected to a pixel circuit for driving the corner pixel PXc and a pixel circuit for driving the main pixel to provide the same scan signal. In this case, a scan line SL connected to the driving circuit SDRV1 may extend from the second corner display area CDA2 to the front display area FDA. The scan line SL may extend in the x direction.

In the second corner display area CDA2, the corner pixel PXc may overlap the driving circuit SDRV1. A pixel circuit PCc for driving the corner pixel PXc located in the second corner display area CDA2 may be located in the first corner display area CDA1. Accordingly, pixel circuits PC1 and PC2 for respectively driving the corner pixel PXc located in the first corner display area CDA1 and the corner pixel PXc located in the second corner display area CDA2 may be located in the first corner display area CDA1. The corner pixel PXc located in the second corner display area CDA2 may be driven by being connected to the pixel circuits PC1 and PC2 located in the first corner display area CDA1 through a connection wiring CWL. The connection wiring CWL may extend in the x direction in which the scan line SL extends.

The corner pixels PXc located in the corner display area CDA may include a first copy pixel CPX1 and a second copy pixel CPX2. The first copy pixel CPX1 and the second copy pixel CPX2 may be driven by one pixel circuit and may emit light of the same color. Sizes of the first copy pixel CPX1 and the second copy pixel CPX2 may be substantially the same. Because the corner pixels PXc include copy pixels, the number of pixel circuits for driving the corner pixels PXc may be reduced, and because the corner pixels PXc overlap the scan driving circuit SDRV1, the corner display area CDA may be extended.

The peripheral area PA may be located outside the side display area SDA and the corner display area CDA. Various wirings, a driving circuit SDRV2, and a terminal unit PAD may be provided in the peripheral area PA.

The driving circuit SDRV2 may provide a scan signal for driving the main pixels PXm and the side pixels PXs. The driving circuit SDRV2 may be located on a right side of the second side display area SDA2 or a left side of the third side display area SDA3, and may be connected to the scan line SL extending in the x direction.

The terminal unit PAD may be located on a lower side of the first side display area SDA1. The terminal unit PAD is exposed without being covered by an insulating layer, and is connected to a display circuit board FPCB. A display driver 32 may be located on the display circuit board FPCB.

The display driver 32 may generate a control signal transmitted to the driving circuits SDRV1 and SDRV2. Also, the display driver 32 may generate a data signal. The generated data signal may be transmitted to a fan-out wiring FW and the pixels PXm, PXs, and PXc through a data line DL connected to the fan-out wiring FW.

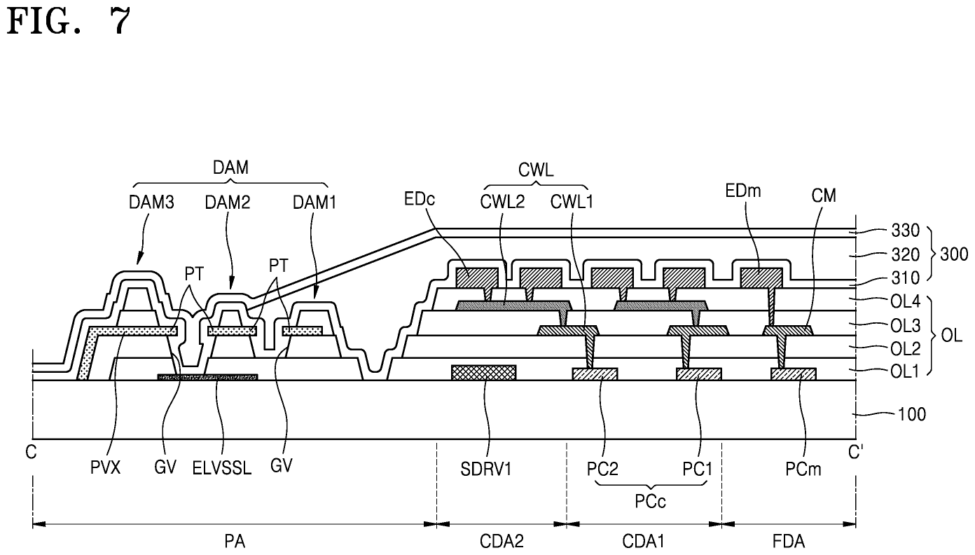

FIG. 7 is a cross-sectional view schematically illustrating a part of the display panel, taken along line C-C′ of FIG. 6, according to an embodiment.

Referring to FIG. 7, the display panel 10 may include the front display area FDA, the corner display area CDA, and the peripheral area PA, and the corner display area CDA may include the first corner display area CDA1 and the second corner display area CDA2.

The substrate 100 may be formed of an insulating material such as glass, quartz, or a polymer resin. The substrate 100 may be a rigid substrate, or a flexible substrate that is bendable, foldable, or rollable.

Pixel circuits (e.g., PCm and PCc) including thin-film transistors, the driving circuit SDRV1 for providing a scan signal to the pixel circuits, main and corner light-emitting elements EDm and EDc connected to the pixel circuits (e.g., PCm and PCc) to implement pixels, a thin-film encapsulation layer 300 covering and protecting the main and corner light-emitting elements EDm and EDc, and a dam unit DAM may be located on the substrate 100. The pixel circuits may include a main pixel circuit PCm and a corner pixel circuit PCc, and the corner pixel circuit PCc may include a first corner pixel circuit PC1 and a second corner pixel circuit PC2. In some embodiments, the main pixel circuit PCm, the first corner pixel circuit PC1, and the second corner pixel circuit PC2 may have the same pixel circuit structure. In another embodiment, the main pixel circuit PCm, the first corner pixel circuit PC1, and the second corner pixel circuit PC2 may have pixel circuit structures that are at least partially modified or are different from each other.

An organic insulating layer OL may be located between the main and corner pixel circuits PCm and PCc and the main and corner light-emitting elements EDm and EDc. The organic insulating layer OL may be provided by stacking a plurality of organic insulating layers. In some embodiments, the organic insulating layer OL may be provided by stacking a first organic insulating layer OL1, a second organic insulating layer OL2, a third organic insulating layer OL3, and a fourth organic insulating layer OL4.

The main pixel circuit PCm and the main light-emitting element EDm connected to the main pixel circuit PCm may be located in the front display area FDA of the display panel 10. An emission area of the main light-emitting element EDm may correspond to the main pixel PXm (see FIG. 6). The main pixel circuit PCm may include at least one thin-film transistor, and may control light emission of the main light-emitting element EDm. The main light-emitting element EDm may be connected to the main pixel circuit PCm through a connection electrode CM. The main light-emitting element EDm may at least partially overlap the main pixel circuit PCm.

The first corner pixel circuit PC1 and the corner light-emitting element EDc connected to the first corner pixel circuit PC1 may be located in the first corner display area CDA1 of the display panel 10. An emission area of the corner light-emitting element EDc may correspond to the corner pixel PXc (see FIG. 6). The first corner pixel circuit PC1 may include at least one thin-film transistor, and may control light emission of at least two corner light-emitting elements EDc. In an embodiment, two corner light-emitting elements EDc may be connected to one first corner pixel circuit PC1 to simultaneously emit light. In this case, the two corner light-emitting elements EDc may implement a copy pixel.

The second corner pixel circuit PC2 connected to the corner light-emitting element EDc located in the second corner display area CDA2 may be located in the first corner display area CDA1. The second corner pixel circuit PC2 may include at least one thin-film transistor, and may control light emission of at least two corner light-emitting elements EDc. In an embodiment, two corner light-emitting elements EDc may be connected to one second corner pixel circuit PC2 to simultaneously emit light. In this case, the two corner light-emitting elements EDc may implement a copy pixel.

The second corner pixel circuit PC2 may be connected to the corner light-emitting element EDc located in the second corner display area CDA2 by the connection wiring CWL connected to the first corner display area CDA1. The connection wiring CWL may include a first connection wiring CWL1 and a second connection wiring CWL2 located on different layers. A connection relationship of the second corner pixel circuit PC2 to the corner light-emitting element EDc may be modified in various ways. For example, the second corner pixel circuit PC2 may be connected to the corner light-emitting element EDc only by the first connection wiring CWL1, may be connected to the corner light-emitting element EDc only by the second connection wiring CWL2, or may be connected to the corner light-emitting element EDc by the first connection wiring CWL1 and the second connection wiring CWL2.

The driving circuit SDRV1 may be located in the second corner display area CDA2 of the display panel 10. The driving circuit SDRV1 may include at least one thin-film transistor, and may provide a scan signal to the main and corner pixel circuits PCc and PCm located in the corner display area CDA and the front display area FDA. An emission control driving circuit (not shown) for providing an emission control signal in addition to a scan signal may be further located in the second corner display area CDA2. The driving circuit SDRV1 and the emission control driving circuit may overlap the corner light-emitting element EDc.

Emission areas of the corner light-emitting elements EDc located in the first corner display area CDA1 and the second corner display area CDA2 may represent corner pixels, and the corner pixels may be arranged in the same pixel arrangement in the first corner display area CDA1 and the second corner display area CDA2.

The main light-emitting element EDm and the corner light-emitting element EDc may be covered by the thin-film encapsulation layer 300. In an embodiment, the thin-film encapsulation layer 300 may include at least one inorganic encapsulation layer and at least one organic encapsulation layer. In an embodiment, the thin-film encapsulation layer 300 may include first and second inorganic encapsulation layers 310 and 330, and an organic encapsulation layer 320 between the first and second inorganic encapsulation layers 310 and 330.

A common voltage line EVLSSL for transmitting a common voltage to a light-emitting element and the dam unit DAM may be located in the peripheral area PA of the display panel 10. The dam unit DAM may overlap the common voltage line ELVSSL. The dam unit DAM may prevent the flow of the organic encapsulation layer 320 of the thin-film encapsulation layer 300, and may prevent penetration of external moisture.

The dam unit DAM may include a plurality of dams. The dam unit DAM may include a first dam DAM1, a second dam DAM2, and a third dam DAM3. A groove GV may be formed in a depth direction between a plurality of dams. The plurality of dams may be provided by stacking a plurality of organic insulating layers OL. Each of the first dam DAM1 and the second dam DAM2 may be provided by stacking the first organic insulating layer OL1, the second organic insulating layer OL2, and the third organic insulating layer OL3.

In the present embodiment, each of the first dam DAM1 and the second dam DAM2 may further include an inorganic layer PVX located between the second organic insulating layer OL2 and the third organic insulating layer OL3. The inorganic layer PVX may include a protruding tip PT protruding toward the center of the groove GV located between the first dam DAM1 and the second dam DAM2. Because an organic layer or a counter electrode included in a light-emitting element is disconnected by the protruding tip, a tolerance margin required to deposit the organic layer or the counter electrode may be reduced, and thus, the area of the peripheral area PA may be significantly reduced.

In the present embodiment, the third dam DAM3 may be provided by stacking the first organic insulating layer OL1, the second organic insulating layer OL2, the third organic insulating layer OL3, and the fourth organic insulating layer OL4. The third dam DAM3 may further include the inorganic layer PVX located between the second organic insulating layer OL2 and the third organic insulating layer OL3. The inorganic layer PVX may cover a side surface of the third dam DAM3 adjacent to an end of the substrate 100. That is, the inorganic layer PVX may cover a side surface of the second organic insulating layer OL2 that is a second layer of the third dam DAM3. The inorganic layer PVX may extend from a side surface of the second organic insulating layer OL2 to a top surface of the substrate 100. Accordingly, the first inorganic encapsulation layer 310 of the thin-film encapsulation layer may contact the inorganic layer PVX on the side surface of the third dam DAM3. The second inorganic encapsulation layer 330 may also contact the first inorganic encapsulation layer 310 on the side surface of the third dam DAM3.

The first inorganic encapsulation layer 310 may clad an end of the inorganic layer PVX on the top surface of the substrate 100, and the second inorganic encapsulation layer 330 may clad an end of the first inorganic encapsulation layer 310 on the top surface of the substrate 100. According to this structure, penetration of external air into the display area may be effectively prevented. Also, because the first inorganic encapsulation layer 310, the second inorganic encapsulation layer 330, and the inorganic layer PVX contact each other on a side surface of the third dam DAM3, the area of the peripheral area may be significantly reduced. As the area of the peripheral area PA decreases, the area of the second corner display area CDA2 may increase, and thus, the area of the display area of the display apparatus 1 may increase.

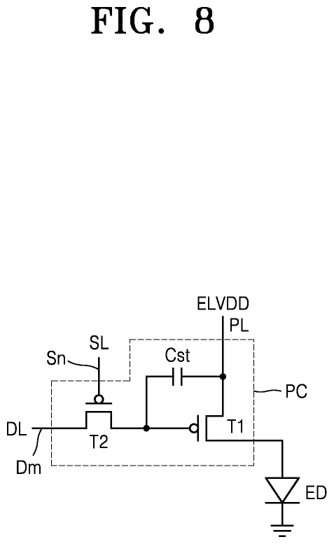

FIG. 8 is an equivalent circuit diagram illustrating a pixel circuit that may be applied to a display panel, according to an embodiment.

Referring to FIG. 8, a pixel circuit PC may be connected to a light-emitting element ED so that (sub-)pixels emit light. The pixel circuit PC may include a driving thin-film transistor T1, a switching thin-film transistor T2, and a storage capacitor Cst. The switching thin-film transistor T2 is connected to a scan line SL and a data line DL, and transmits a data signal Dm input through the data line DL to the driving thin-film transistor T1 according to a scan signal Sn input through the scan line SL.

The storage capacitor Cst is connected to the switching thin-film transistor T2 and a driving voltage line PL, and stores a voltage corresponding to a difference between a voltage received from the switching thin-film transistor T2 and a driving voltage ELVDD supplied to the driving voltage line PL.

The driving thin-film transistor T1 may be connected to the driving voltage line PL and the storage capacitor Cst, and may control driving current flowing from the driving voltage line PL to an anode of the light-emitting element ED in response to a value of the voltage stored in the storage capacitor Cst. A cathode of the light-emitting element ED may be connected to a common voltage ELVSS. The light-emitting element ED may emit light having a certain luminance due to the driving current.

Although the pixel circuit PC includes two thin-film transistors and one storage capacitor in FIG. 8, the disclosure is not limited thereto. Various modifications may be made. For example, the pixel circuit PC may include three to nine thin-film transistors and one to two capacitors. The pixel circuit PC may be equally applied to the main pixel circuit PCm and the corner pixel circuit PCc, or may be applied after some elements are modified. For example, a capacitance of a storage capacitor included in the main pixel circuit PCm and a capacitance of a storage capacitor included in the corner pixel circuit PCc may be different from each other. Alternatively, various modifications may be made. For example, the number of thin-film transistors included in the main pixel circuit PCm and the number of thin-film transistors included in the corner pixel circuit PCc may be different from each other.

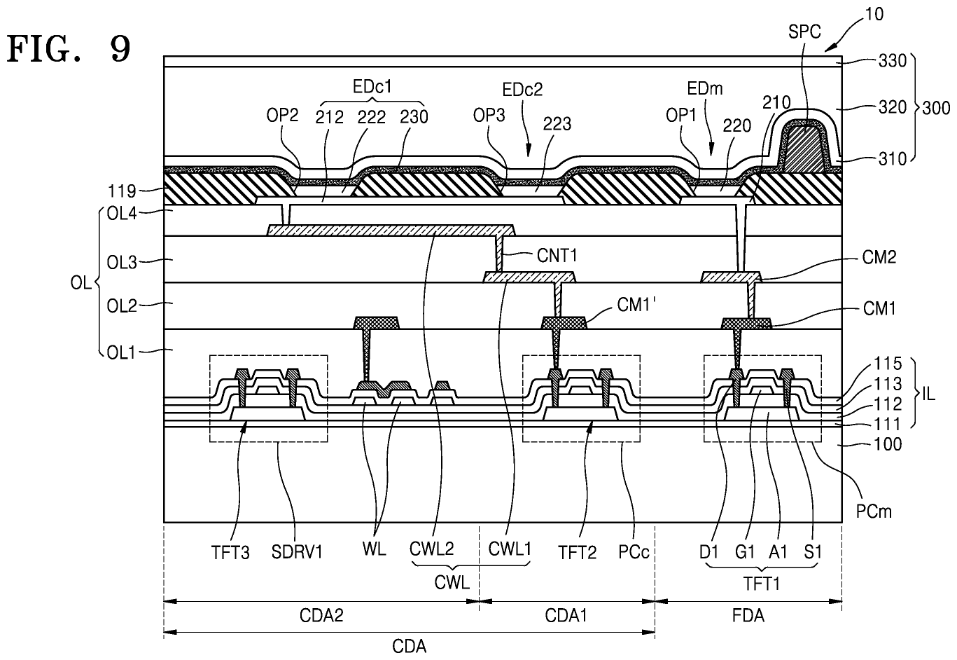

A structure in which elements included in the display panel 10 are stacked will be described in detail with reference to FIG. 9.

FIG. 9 is a cross-sectional view schematically illustrating a portion of a display panel, according to an embodiment.

Referring to FIG. 9, the main light-emitting element EDm and the main pixel circuit PCm connected to the main light-emitting element EDm may be located in the front display area FDA. Corner light-emitting elements (e.g., EDc1 and EDc2) may be located as a corner light-emitting element in the corner display area CDA. The corner light-emitting elements may include a first corner light-emitting element EDc1 and a second corner light-emitting element EDc2 that are connected to each other. The main light-emitting element EDm, and the first and second corner light-emitting elements EDc1 and EDc2 may be provided as organic light-emitting diodes.

The corner pixel circuit PCc connected to the first and second corner light-emitting elements EDc1 and EDc2 may be located in the first corner display area CDA1 of the corner display area CDA. The driving circuit SDRV1 for providing a driving signal such as a scan signal to the main and corner pixel circuits PCm and PCc may be located in the second corner display area CDA2. The main pixel circuit PCm may include a first thin-film transistor TFT1, the corner pixel circuit PCc may include a second thin-film transistor TFT2, and the driving circuit SDRV1 may include a third thin-film transistor TFT3.

The connection wiring CWL for connecting the corner pixel circuit PCc to the first and second corner light-emitting elements EDc1 and EDc2 may be located in the first corner display area CDA1 and the second corner display area CDA2. The connection wiring CWL may include the first connection wiring CWL1 and the second connection wiring CWL2 located on different layers.

The substrate 100 may be formed of an insulating material such as glass, quartz, or a polymer resin. The substrate 100 may be a rigid substrate, or a flexible substrate that is bendable, foldable, or rollable.

A buffer layer 111 may be located on the substrate 100, and may reduce or prevent penetration of a foreign material, moisture, or external air from the bottom of the substrate 100 and may planarize the substrate 100. The buffer layer 111 may include an inorganic material such as oxide or nitride, an organic material, or a combination of an organic material and an inorganic material, and may have a single or multi-layer structure including an inorganic material and an organic material. A barrier layer (not shown) may be further provided between the substrate 100 and the buffer layer 111 to prevent penetration of external air. In some embodiments, the buffer layer 111 may include silicon oxide (SiO₂) or silicon nitride (SiN_{X}).

The first thin-film transistor TFT1, the second thin-film transistor TFT2, and the third thin-film transistor TFT3 may be located on the buffer layer 111. The first thin-film transistor TFT1 includes a first semiconductor layer A1, a first gate electrode G1, a first source electrode S1, and a first drain electrode D1. The first thin-film transistor TFT1 may be connected to the main light-emitting element EDm to drive the main light-emitting element EDm. The second thin-film transistor TFT2 may be connected to the first and second corner light-emitting elements EDc1 and EDc2 to drive the first and second corner light-emitting elements EDc1 and EDc2. The third thin-film transistor TFT3 may provide a driving signal such as a scan signal to a thin-film transistor included in the driving circuit SDRV1.

Because the second thin-film transistor TFT2 and the third thin-film transistor TFT3 include a configuration similar to that of the first thin-film transistor TFT1, the description of the first thin-film transistor TFT1 may apply to the second thin-film transistor TFT2 and the third thin-film transistor TFT3. The first thin-film transistor TFT1 may include the first semiconductor layer A1, the first gate electrode G1, the first source electrode S1, and the first drain electrode D1.

The first semiconductor layer A1 may be located on the buffer layer 111, and may include polysilicon. In another embodiment, the first semiconductor layer A1 may include amorphous silicon. In another embodiment, the first semiconductor layer A1 may include an oxide of at least one material selected from the group consisting of indium (In), gallium (Ga), stannum (Sn), zirconium (Zr), vanadium (V), hafnium (Hf), cadmium (Cd), germanium (Ge), chromium (Cr), titanium (Ti), and zinc (Zn). The first semiconductor layer A1 may include a channel region, and a source region and a drain region doped with impurities.

A first gate insulating layer 112 may be provided to cover the first semiconductor layer A1. The first gate insulating layer 112 may include an inorganic insulating material such as silicon oxide (SiO₂), silicon nitride (SiN_{X}), silicon oxynitride (SiOₓN_{y}), aluminum oxide (Al₂O₃), titanium oxide (TiO₂), tantalum oxide (Ta₂O₅), or hafnium oxide (HfO₂). The first gate insulating layer 112 may have a single or multi-layer structure including the inorganic insulating material.

The first gate electrode G1 is located on the first gate insulating layer 112 to overlap the first semiconductor layer A1. The first gate electrode G1 may include molybdenum (Mo), aluminum (Al), copper (Cu), or titanium (Ti), and may have a single or multi-layer structure. For example, a first gate electrode G1 may have a single-layer structure including Mo.

A second gate insulating layer 113 may be provided to cover the first gate electrode G1. The second gate insulating layer 113 may include an inorganic insulating material such as silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), or zinc oxide (ZnO₂). The second gate insulating layer 113 may have a single or multi-layer structure including the inorganic insulating material.

Wirings WL and a capacitor electrode (not shown) may be located on the second gate insulating layer 113. Some of the wirings WL located in the second corner display area CDA2 may be connected to the driving circuit SDRV1 to transmit driving signals. The wirings WL may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (TI), tungsten (W), or copper (Cu), and may have a single or multi-layer structure including the above material.

An interlayer insulating layer 115 may be formed on the second gate insulating layer 113 to cover the wirings WL. The interlayer insulating layer 115 may include silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), or hafnium oxide (HfO₂). The interlayer insulating layer 115 may have a single or multi-layer structure including the inorganic insulating material.

The first source electrode S1 and the first drain electrode D1 may be located on the interlayer insulating layer 115. Each of the first source electrode S1 and the first drain electrode D1 may include a conductive material including molybdenum (Mo), aluminum (Al), copper (Cu), or titanium (Ti), and may have a single or multi-layer structure including the above material. For example, each of the first source electrode S1 and the first drain electrode D1 may have a multi-layer structure including Ti/Al/Ti.

The first organic insulating layer OL1 may be located on the interlayer insulating layer 115 to cover the first source electrode S1 and the first drain electrode D1. First connection electrodes CM1 and CM1′ respectively connected to the main and corner pixel circuits PCm and PCc may be located on the first organic insulating layer OL1. Each of the first connection electrodes CM1 and CM1′ may include a conductive material including molybdenum (Mo), aluminum (Al), copper (Cu), or titanium (Ti), and may have a single or multi-layer structure including the above material.

The buffer layer 111, the first gate insulating layer 112, the second gate insulating layer 113, and the interlayer insulating layer 115 may be collectively referred to as an inorganic insulating layer IL. The inorganic insulating layer IL may be located between the substrate 100 and the light-emitting elements (e.g., EDm, EDc1, and EDc2), or between the substrate 100 and the organic insulating layer OL.

The second organic insulating layer OL2 at least partially covering the first connection electrodes CM1 and CM1′ may be located on the first organic insulating layer OL1. The first connection wirings CWL1 and a second connection electrode CM2 may be located on the second organic insulating layer OL2. The first connection wirings CWL1 may be connected to the first connection electrode CM1′ connected to the corner pixel circuit PCc, and the second connection electrode CM2 may be connected to the first connection electrode CM1 connected to the main pixel circuit PCm.

Each of the first connection wirings CWL1 and the second connection electrode CM2 may include a conductive material including molybdenum (Mo), aluminum (Al), copper (Cu), or titanium (Ti), and may have a single or multi-layer structure including the above material. Alternatively, each of the first connection wirings CWL1 and the second connection electrode CM2 may be formed of a transparent conductive material. For example, each of the first connection wirings CWL1 and the second connection electrode CM2 may include a transparent conductive oxide (TCO). Each of the first connection wirings CWL1 and the second connection electrode CM2 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO).

The third organic insulating layer OL3 at least partially covering the first connection wiring CWL1 may be located on the second organic insulating layer OL2. The second connection wiring CWL2 may be located on the third organic insulating layer OL3. The second connection wirings CWL2 may be connected to the first connection wiring CWL1 through a contact hole CNT1 passing through the third organic insulating layer OL3.

The second connection wirings CWL2 may include a conductive material including molybdenum (Mo), aluminum (Al), copper (Cu), or titanium (Ti), and may have a single or multi-layer structure including the above material. Alternatively, the second connection wirings CWL2 may be formed of a transparent conductive material. For example, the second connection wirings CWL2 may be formed of a transparent conductive oxide (TCO). The second connection wirings CWL2 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO).

At least one of the first connection wirings CWL1 and the second connection wirings CWL2 may extend from the first corner display area CDA1 to the second corner display area CDA2. Accordingly, at least one of the first connection wirings CWL1 and the second connection wirings CWL2 may overlap the driving circuit SDRV1.

The fourth organic insulating layer OLA at least partially covering the second connection wirings CWL2 may be located on the third organic insulating layer OL3. The fourth organic insulating layer OL4 may have a flat top surface so that a first pixel electrode 210 and a second pixel electrode 212 located on the fourth organic insulating layer OL4 are formed flat.

Each of the first organic insulating layer OL1, the second organic insulating layer OL2, the third organic insulating layer OL3, and the fourth organic insulating layer OL4 may include benzocyclobutene (BCB), polyimide, hexamethyldisiloxane (HMDSO), a general-purpose polymer such as polymethyl methacrylate (PMMA) or polystyrene (PS), a polymer derivative having a phenol-based group, an acrylic polymer, an imide-based polymer, an aryl ether-based polymer, an amide-based polymer, a fluorinated polymer, a p-xylene-based polymer, or a vinyl alcohol-based polymer. Various modifications may be made. For example, the first organic insulating layer OL1, the second organic insulating layer OL2, the third organic insulating layer OL3, and the fourth organic insulating layer OL4 may be formed of the same material or different materials.

The light-emitting elements (e.g., EDm, EDc1, and EDc2) may be located on the fourth organic insulating layer OL4. The main light-emitting element EDm may include the first pixel electrode 210, a first emission layer 220, and a counter electrode 230. The first corner light-emitting element EDc1 may include the second pixel electrode 212, a second emission layer 222, and the counter electrode 230, and the second corner light-emitting element EDc2 may include the second pixel electrode 212, a third emission layer 223, and the counter electrode 230. The first corner light-emitting element EDc1 and the second corner light-emitting element EDc2 may share the second pixel electrode 212.

Each of the first pixel electrode 210 and the second pixel electrode 212 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). Each of the first pixel electrode 210 and the second pixel electrode 212 may include a reflective film including silver (Ag), magnesium (Mg), aluminum (Al), platinum (Pt), palladium (Pd), gold (Au), nickel (Ni), neodymium (Nd), iridium (Ir), chromium (Cr), or a compound thereof. For example, each of the first pixel electrode 210 and the second pixel electrode 212 may have a structure in which films formed of ITO, IZO, ZnO, or In₂O₃ are located over/under the reflective film. In this case, each of the first pixel electrode 210 and the second pixel electrode 212 may have a stacked structure including ITO/Ag/ITO.

A bank layer 119 may be located on the fourth organic insulating layer OL4, and may define emission areas of the light-emitting elements (e.g., EDm, EDc1, and EDc2). The bank layer 119 may cover an edge of the first pixel electrode 210, and may include a first opening OP1 through which a central portion of the first pixel electrode 210 is exposed. A size and a shape of an emission area of the main light-emitting element EDm may be defined by the first opening OP1.

The bank layer 119 may cover an edge of the second pixel electrode 212, and may include a second opening OP2 and a third opening OP3 through which two portions of the second pixel electrode 212 are exposed. The second opening OP2 may define an emission area of the first corner light-emitting element EDc1, and the third opening OP3 may define an emission area of the second corner light-emitting element EDc2. In some embodiments, sizes and shapes of the second opening OP2 and the third opening OP3 may be the same.

The bank layer 119 may increase a distance between edges of the first and second pixel electrodes 210 and 212 and the counter electrode 230 located over the first and second pixel electrodes 210 and 212, to prevent an arc or the like from occurring on the edges of the first and second pixel electrodes 210 and 212. The bank layer 119 may be formed of an organic insulating material such as polyimide, polyamide, acrylic resin, benzocyclobutene, hexamethyldisiloxane (HMDSO), or phenolic resin, by using spin coating or the like.

A spacer SPC may be located on a top surface of the bank layer 119. The spacer SPC may be provided to prevent mask damage during a process. The spacer SPC may be formed of an organic insulating material such as polyimide, polyamide, acrylic resin, benzocyclobutene, hexamethyldisiloxane (HMDSO), or phenolic resin, by using spin coating or the like.

The first emission layer 220, the second emission layer 222, and the third emission layer 223 may be respectively located in the first opening OP1, the second opening OP2, and the third opening OP3 of the bank layer 119. Each of the first emission layer 220, the second emission layer 222, and the third emission layer 223 may include a high molecular weight material or a low molecular weight material, and may emit red light, green light, blue light, or white light. In an embodiment, the second emission layer 222 and the third emission layer 223 may be formed of the same material, and may emit light of the same color.

An organic functional layer (not shown) may be located over or under the first emission layer 220, the second emission layer 222, and the third emission layer 223. An organic functional layer of the first emission layer 220, the second emission layer 222, and the third emission layer 223 may include a hole injection layer (HIL), a hole transport layer (HTL), an electron transport layer (ETL), or an electron injection layer (EIL). The organic functional layer may be integrally formed to correspond to light-emitting elements included in the front display area FDA and the corner display area CDA.

The counter electrode 230 may be located on the first emission layer 220, the second emission layer 222, and the third emission layer 223. The counter electrode 230 may include a conductive material having a low work function. For example, the counter electrode 230 may include a (semi-)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. Alternatively, the counter electrode 230 may further include a layer formed of ITO, IZO, ZnO, or In₂O₃ on the (semi-)transparent layer including the above material. The counter electrode 230 may be integrally formed to correspond to the light-emitting elements (e.g., EDm, EDc1, and EDc2) included in the front display area FDA and the corner display area CDA.

An upper layer (not shown) including an organic material may be formed on the counter electrode 230. The upper layer may protect the counter electrode 230 and may improve light extraction efficiency. The upper layer may include an organic material having a higher refractive index than that of the counter electrode 230. Alternatively, the upper layer may be formed by stacking layers having different refractive indexes. For example, the upper layer may be formed by stacking a high refractive index layer, a low refractive index layer, and a high refractive index layer. In this case, a refractive index of the high refractive index layer may be equal to or greater than 1.7, and a refractive index of the low refractive index layer may be equal to or less than 1.3.

The upper layer may additionally include LiF. Alternatively, the upper layer may additionally include an inorganic insulating material such as silicon oxide (SiO₂) or silicon nitride (SiNₓ).

The light-emitting elements (e.g., EDm, EDc1, and EDc2) may be covered and protected by the thin-film encapsulation layer 300. The thin-film encapsulation layer 300 may include at least one organic encapsulation layer and at least one inorganic encapsulation layer. In FIG. 9, the thin-film encapsulation layer 300 includes the first and second inorganic encapsulation layers 310 and 330, and the organic encapsulation layer 320 located between the first and second inorganic encapsulation layers 310 and 330. In another embodiment, the number of organic encapsulation layers, the number of inorganic encapsulation layers, and an order in which layers are stacked may be changed.

Each of the first inorganic encapsulation layer 310 and the second inorganic encapsulation layer 330 may include at least one inorganic insulating material such as silicon oxide (SiO₂), silicon nitride (SiNₓ), or silicon oxynitride (SiOₓN_{y}), and may be formed by using chemical vapor position (CVD) or the like. The organic encapsulation layer 320 may include a polymer-based material. Examples of the polymer-based material may include an acrylic resin, an epoxy resin, polyimide, and polyethylene.

In the present embodiment, the corner pixel circuit PCc may be located in the first corner display area CDA1, and one corner pixel circuit PCc and at least two corner light-emitting elements (e.g., EDc1 and EDc2) may be connected to each other. For example, one corner pixel circuit PCc may be connected to the first corner light-emitting element EDc1 and the second corner light-emitting element EDc2. Although one corner pixel circuit PCc and two corner light-emitting element s EDc1, EDc2 are connected to each other in FIG. 9, the disclosure is not limited thereto. Various modifications may be made. For example, one corner pixel circuit PCc and three or four corner light-emitting diodes may be connected to each other.

The corner pixel circuit PCc may be connected to the first and second corner light-emitting elements EDc1 and EDc2 through the connection wiring CWL extending from the first corner display area CDA1 to the second corner display area CDA2. The connection wiring CWL may include the first connection wiring CWL1 located on the second organic insulating layer OL2 and the second connection wiring CWL2 located on the third organic insulating layer OL3.

Each of the second connection wirings CWL2 may be connected to the first connection wiring CWL1 through the contact hole CNT1 passing through the third organic insulating layer OL3. Because the first connection wiring CWL1 is connected to the first connection electrode CM1′ connected to the corner pixel circuit PCc through a contact hole, and each second connection wiring CWL2 is connected to the second pixel electrode 212 through a contact hole, the corner pixel circuit PCc may be connected to the first and second corner light-emitting elements EDc1 and EDc2.

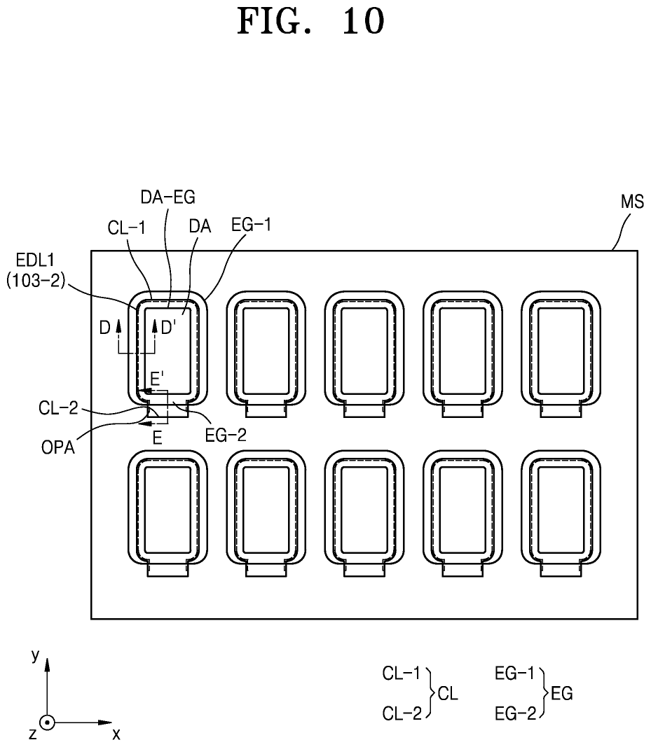

FIG. 10 is a plan view illustrating an arrangement of a mother substrate and a display panel for manufacturing a display panel, according to an embodiment.

Referring to FIG. 10, a mother substrate shown in FIG. 5 may be located on a support substrate MS. In this case, the mother substrate may include the same material as that of the substrate shown in FIG. 9, and the mother substrate may be located on an entire surface of the support substrate MS. In this case, at least one display unit located in the display area DA and a thin-film encapsulation layer covering the display unit may be located on the mother substrate. In this case, the display unit may include layers extending from the buffer layer to the counter electrode of FIG. 9. Also, the thin-film encapsulation layer may include the first inorganic encapsulation layer, the organic encapsulation layer, and the second inorganic encapsulation layer of FIG. 9. For convenience of explanation, the following will be described assuming that a plurality of display units are provided on the support substrate MS.

A first end DA-EG of the display area DA located on the support substrate MS may be located inside a cutting line CL. The cutting line CL may include a first cutting line CL-1 located to surround at least a part of the display area DA and a second cutting line CL-2 connected to the first cutting line CL-1 and located to correspond to at least a part of the terminal unit of FIG. 5.

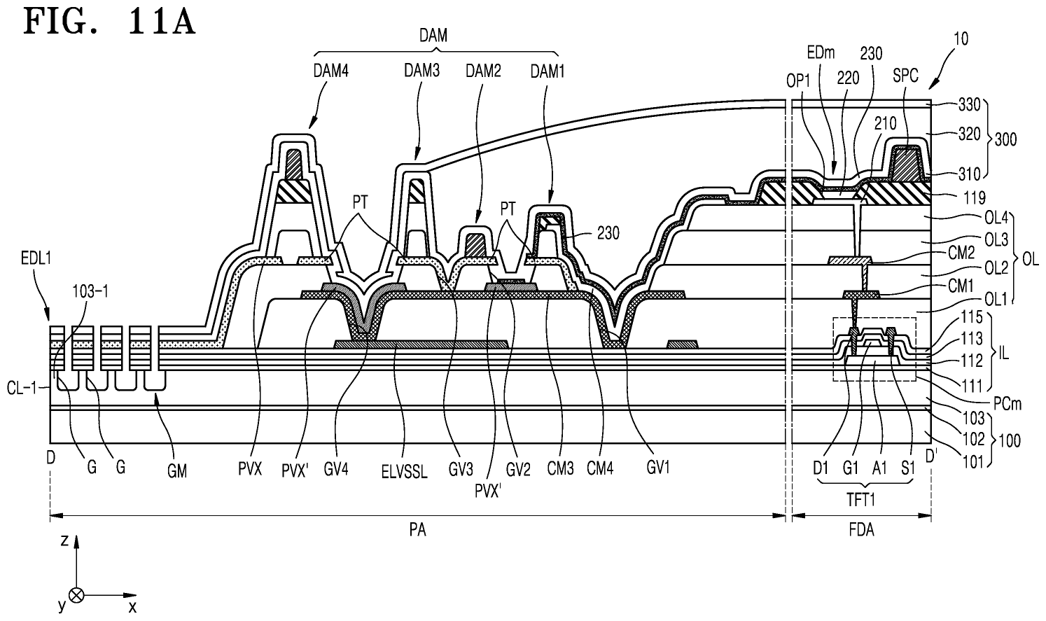

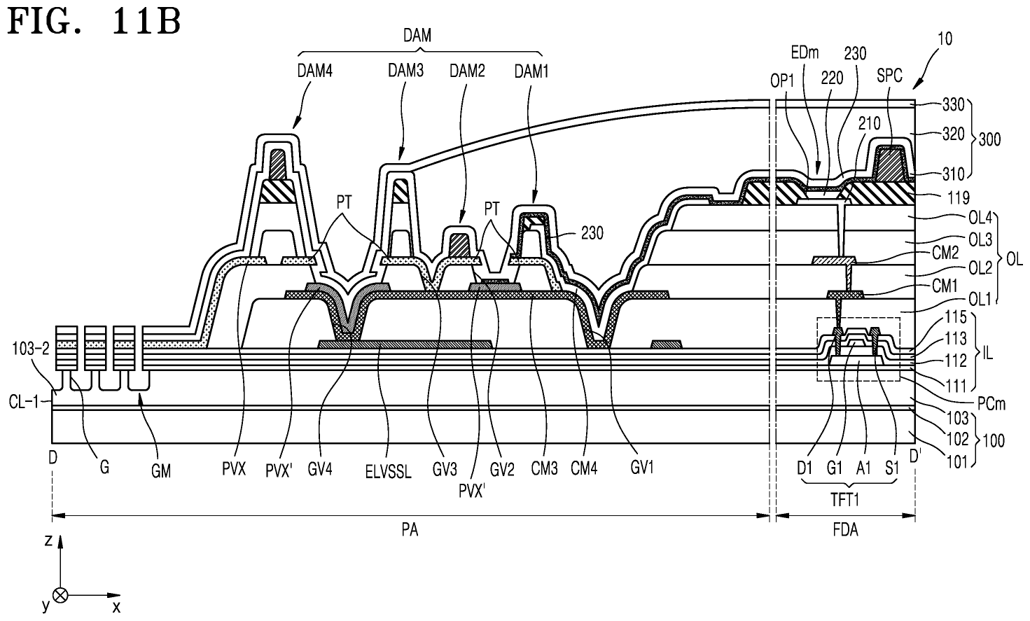

In the above case, a second end EG of at least one of a second barrier layer (not shown), a buffer layer (not shown), a first gate insulating layer (not shown), a second gate insulating layer (not shown), an interlayer insulating layer (not shown), an inorganic layer (not shown), the first inorganic encapsulation layer, and the second inorganic encapsulation layer of the substrate described below may be located outside at least a part of an outer edge of the first end DA-EG. For example, the second end EG may surround the first end DA-EG. The second end EG may include a 2-1^{th} end EG-1 located to correspond to the first cutting line CL-1, and a 2-2^{th} end EG-2 located to correspond to the second cutting line CL-2. Also, although not shown, the dam unit (not shown) of FIG. 7 or FIG. 11A described below may be located between the cutting line CL and the first end DA-EG.

In the above case, the substrate may be separated from the mother substrate along the cutting line CL. In this case, a plurality of grooves may be located in the substrate. Accordingly, when the substrate is separated from the mother substrate along the cutting line CL, damage to the substrate may be prevented. An edge of a display panel including the substrate separated from the mother substrate will be described in detail.

In the above case, a first edge inorganic layer EDL1 or an edge groove 103-2 described below may be located on the first cutting line CL-1. In this case, the first edge inorganic layer EDL1 may include a planarization area OPA in which a part is open, or the edge groove 103-2 may include a planarization area OPA in which the edge groove 103-2 is cut. The planarization area OPA may be an area in which the first edge inorganic layer EDL1 or the edge groove 103-2 does not exist. The planarization area OPA may be an area through which a wiring is connected to the terminal unit. In this case, a groove described below may not be located in the planarization area OPA.

The planarization area OPA may have a size similar to that of the second cutting line CL-2. In the above case, although the first edge inorganic layer EDL1 or the edge groove 103-2 extends to a straight portion of a portion corresponding to the terminal unit (not shown) of FIG. 5 in FIG. 10, the disclosure is not limited thereto. For example, the first edge inorganic layer EDL1 or the edge groove 103-2 may be formed only to a curved portion located under the display area DA. In another embodiment, the first edge inorganic layer EDL1 or the edge groove 103-2 may be connected to the entire straight portion of the portion corresponding to the terminal unit. In this case, the first edge inorganic layer EDL1 or the edge groove 103-2 may be connected to the second cutting line CL-2, and the planarization area OPA may correspond to the second cutting line CL-2.

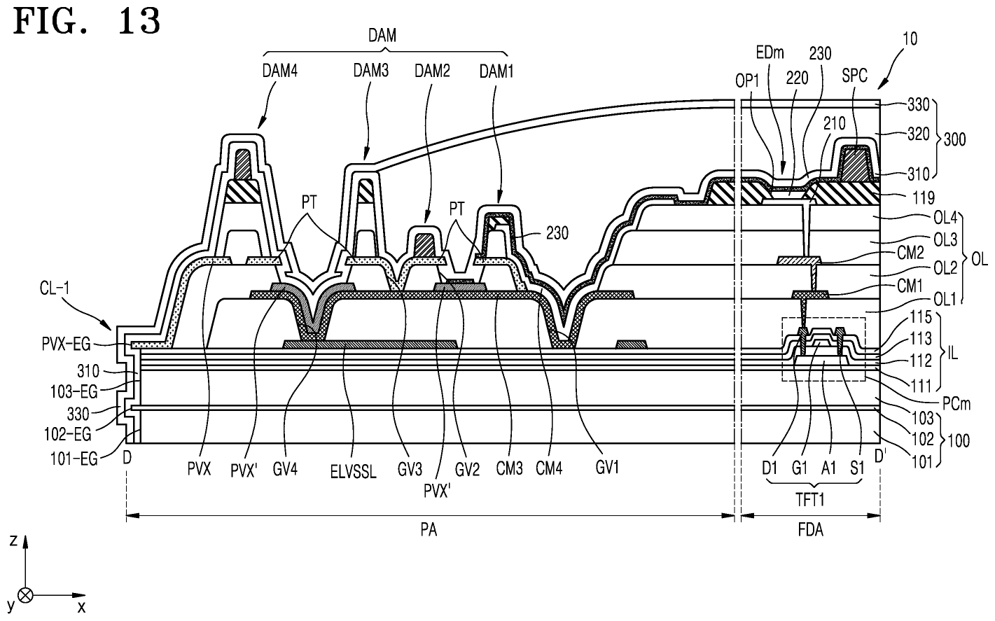

In the above case, at least one groove (not shown) described below may be located so that a side close to the terminal unit is open, like the first edge inorganic layer EDL1 or the edge groove 103-2. In this case, the groove may be located between either the first edge inorganic layer EDL1 or the edge groove 103-2 and the display area DA. When a plurality of grooves are provided, a plurality of layers located between adjacent grooves may include an opening area, like the groove. Also, although not shown in FIG. 10, the dam unit (not shown) of FIG. 7, FIG. 11A, FIG. 11B, or FIG. 13 described below may be located between the groove and the display area DA. In this case, the dam unit may be located in a closed-loop shape, like the second end EG of FIG. 10, in a plan view. In this case, the dam unit may completely surround the display area DA.

FIG. 11A is a cross-sectional view schematically illustrating a part of the display panel, taken along line D-D′ of FIG. 10, according to an embodiment.

Referring to FIG. 11A, the dam unit DAM including a plurality of dams may be located in the peripheral area PA. The dam unit DAM may be a member for blocking the flow of an organic material for forming the organic encapsulation layer 320 when the organic encapsulation layer 320 of the thin-film encapsulation layer 300 is formed.

The dam unit DAM may include a first dam DAM1, a second dam DAM2, a third dam DAM3, and a fourth dam DAM4. The first dam DAM1, the second dam DAM2, the third dam DAM3, and the fourth dam DAM4 may be provided by stacking a plurality of organic layers and the inorganic layer PVX.

The inorganic layer PVX may be formed of an inorganic insulating material. For example, the inorganic layer PVX may have a single or multi-layer structure including an inorganic insulating material such as silicon oxide (SiO₂) or silicon nitride (SiNₓ). When the inorganic layer PVX is formed of an inorganic insulating material, the inorganic layer PVX may be formed through a separate mask process.

In another embodiment, the inorganic layer PVX may be formed of a metal material. For example, the inorganic layer PVX may include a metal material such as molybdenum (Mo), aluminum (Al), copper (Cu), or titanium (Ti), and may have a single or multi-layer structure including the above material. When the inorganic layer PVX is formed of a metal material, the inorganic layer PVX and the second connection electrode CM2 may be simultaneously formed by using the same material.

The first dam DAM1 that is a dam closest to the display area may be provided by stacking a first layer formed of the same material as that of the first organic insulating layer OL1, a second layer formed of the same material as that of the second organic insulating layer OL2, a third layer formed of the inorganic layer PVX, a fourth layer formed of the same material as that of the third organic insulating layer OL3, and a fifth layer formed of the same material as that of the bank layer 119.

The first dam DAM1 may be spaced apart from the organic insulating layer OL extending from the display area. A first groove GV1 may be formed between the first dam DAM1 and the organic insulating layer OL. That is, the first groove GV1 through which a top surface of the inorganic insulating layer IL is exposed may be formed between the dam unit DAM and the organic insulating layer OL. As the first groove GV1 is formed, penetration of external air into the display area may be prevented.

The second dam DAM2 that is located outside the first dam DAM1 may be provided by stacking a first layer formed of the same material as that of the first organic insulating layer OL1, a second layer formed of the same material as that of the second organic insulating layer OL2, a third layer formed of the inorganic layer PVX, and a fourth layer formed of the same material as that of the spacer SPC. A height of the second dam DAM2 may be less than that of the first dam DAM1.

The first dam DAM1 and the second dam DAM2 may share the first layer. A second groove GV2 may be located between the second layer of the first dam DAM1 and the second layer of the second dam DAM2, and the second layer of the first dam DAM1 and the second layer of the second dam DAM2 may be spaced apart from each other. The inorganic layer PVX may include the protruding tip PT protruding toward the second groove GV2 between the first dam DAM1 and the second dam DAM2. The counter electrode 230 may be disconnected by the protruding tip PT. Because the counter electrode 230 included in a light-emitting element is disconnected by the protruding tip PT, a tolerance margin required to deposit the counter electrode 230 may be reduced and thus, the area of the peripheral area PA may be significantly reduced.

The third dam DAM3 that is located outside the second dam DAM2 may be provided by stacking a first layer formed of the same material as that of the first organic insulating layer OL1, a second layer formed of the same material as that of the second organic insulating layer OL2, a third layer formed of the inorganic layer PVX, a fourth layer formed of the same material as that of the third organic insulating layer OL3, a fifth layer formed of the same material as that of the fourth organic insulating layer OL4, and a sixth layer formed of the same material as that of the bank layer 119. A height of the third dam DAM3 may be greater than those of the first dam DAM1 and the second dam DAM2.

The second dam DAM2 and the third dam DAM3 may share the first layer and the third layer. A third groove GV3 may be located between the second layer of the second dam DAM2 and the second layer of the third dam DAM3, and the second layer of the second dam DAM2 and the second layer of the third dam DAM3 may be spaced apart from each other.

The fourth dam DAM4 may be an outermost dam from among the plurality of dams of the dam unit DAM. The fourth dam DAM4 may be provided by stacking a first layer formed of the same material as that of the first organic insulating layer OL1, a second layer formed of the same material as that of the second organic insulating layer OL2, a third layer formed of the inorganic layer PVX, a fourth layer formed of the same material as that of the third organic insulating layer OL3, a fifth layer formed of the same material as that of the fourth organic insulating layer OL4, a sixth layer formed of the same material as that of the bank layer 119, and a seventh layer formed of the same material as that of the spacer SPC. A height of the fourth dam DAM4 may be greater than that of the third dam DAM3. The inorganic layer PVX may cover a top surface and a side surface of the second layer formed of the same material as that of the second organic insulating layer OL2.

A fourth groove GV4 may be located between the first layer of the third dam DAM3 and the first layer of the fourth dam DAM4, and the first layer of the third dam DAM3 and the first layer of the fourth dam DAM4 may be spaced apart from each other. The common voltage line ELVSSL may be located under the third dam DAM3 and the fourth dam DAM4. The common voltage line ELVSSL that is a wiring for transmitting a common voltage to light-emitting elements may be electrically connected to the counter electrode 230.

In some embodiments, the common voltage line ELVSSL may be connected to the counter electrode 230 through a third connection electrode CM3 and a fourth connection electrode CM4. The fourth groove GV4 may function as a contact hole through which the common voltage line ELVSSL and the third connection electrode CM3 are connected to each other. The common voltage line ELVSSL may be located on the same layer as the first source electrode S1 or the first drain electrode D1 of the first thin-film transistor TFT1. The common voltage line ELVSSL may be located on the interlayer insulating layer 115. The common voltage line ELVSSL may be exposed through the fourth groove GV4. The third connection electrode CM3 and the first connection electrode CM1 may be formed on the same layer by using the same material. The third connection electrode CM3 may be located on the first layer of the first dam DAM1 to the fourth dam DAM4 and the first organic insulating layer OL1.

The third connection electrode CM3 may directly contact the common voltage line ELVSSL through the fourth groove GV4. The third connection electrode CM3 may extend from the fourth groove GV4 to the first groove GV1. The third connection electrode CM3 may directly contact the fourth connection electrode CM4 on a side surface of the first dam DAM1 or in the first groove GV1. The fourth connection electrode CM4 and the first pixel electrode 210 may be formed of the same material. The fourth connection electrode CM4 may directly contact the counter electrode 230 in or around the first groove GV1.

The organic encapsulation layer 320 may extend to the third dam DAM3. However, the disclosure is not limited thereto. Various modifications may be made. For example, the organic encapsulation layer 320 may extend to the fourth dam DAM4.

The first inorganic encapsulation layer 310 and the second inorganic encapsulation layer 330 may contact each other from a portion of the dam unit DAM, and may pass through the dam unit DAM and may extend to an end of the substrate 100. For example, the first inorganic encapsulation layer 310 and the second inorganic encapsulation layer 330 may contact each other from a top surface of the third dam DAM3, and may extend to an end of the substrate 100.

The inorganic layer PVX included in the fourth dam DAM4 that is an outermost dam may be at least partially located on a side surface of the fourth dam DAM4, e.g., a side surface of the fourth dam DAM4 close to an end of the substrate 100. The first inorganic encapsulation layer 310 may directly contact the inorganic layer PVX on a side surface of the fourth dam DAM4. The second inorganic encapsulation layer 330 may directly contact the first inorganic encapsulation layer 310 on a side surface of the fourth dam DAM4.

When the inorganic layer PVX is not located on a side surface of the fourth dam DAM4 that is an outermost dam, in order for the thin-film encapsulation layer 300 to block external air, the first inorganic encapsulation layer 310 should contact a top surface of the inorganic insulating layer IL extending from the display area by a certain area or more.

However, because the inorganic layer PVX is located on a side surface of the fourth dam DAM4 to secure a contact area with inorganic films on a side surface of the fourth dam DAM4, external air may be sufficiently blocked even when a contact area with the inorganic insulating layer IL on a top surface of the substrate 100 is reduced. Accordingly, the area of the peripheral area PA may be reduced. As the area of the peripheral area PA decreases, the area of the display area of the display apparatus 1 may increase.

The first inorganic encapsulation layer 310 may clad an end of the inorganic layer PVX on a top surface of the substrate 100, and the second inorganic encapsulation layer 330 may clad an end of the first inorganic encapsulation layer 310 on a top surface of the substrate 100. According to this structure, penetration of external air into the display area may be effectively prevented.

Although the first inorganic encapsulation layer 310 and the second inorganic encapsulation layer 330 are spaced apart from an end of the substrate 100, the disclosure is not limited thereto. Unlike this, the first inorganic encapsulation layer 310 and the second inorganic encapsulation layer 330 may extend to an end of the substrate 100.

The substrate 100 may have a multi-layer structure. For example, the substrate 100 may include a first base layer 101, a first barrier layer 102, a second base layer 103, and a second barrier layer (not shown) which are sequentially stacked.

Each of the first and second base layers 101 and 103 may include a polymer resin. For example, each of the first and second base layers 101 and 103 may include a polymer resin such as polyethersulfone (PES), polyarylate (PAR), polyetherimide (PEI), polyethylene napthalate (PEN), polyethylene terephthalate (PET), polyphenylene sulfide (PPS), polyarylate, polyimide (PI), polycarbonate (PC), cellulose triacetate (TAC), or cellulose acetate propionate (CAP). The polymer resin may be transparent.

Each of the first barrier layer 102 and the second barrier layer which is a barrier layer for preventing penetration of an external foreign material may have a single or multi-layer structure including an inorganic material such as silicon nitride (SiNₓ) or silicon oxide (SiO₂).

In the present embodiment, a plurality of grooves G formed by removing a part of the inorganic insulating layer IL and the substrate 100 may be located between an end of the substrate 100 and the damn unit DAM. For example, the plurality of grooves G may be formed by connecting a hole passing through the inorganic insulating layer IL to a recess formed in the second base layer 103 of the substrate 100. The inorganic insulating layer IL may include a protruding tip protruding into the groove G. The plurality of grooves G may be provided to prevent propagation of cracks that may occur when the end of the substrate 100 is cut.

In the present embodiment, an inorganic protective layer PVX′ may be located on the third connection electrode CM3. The inorganic protective layer PVX′ may cover a part of the third connection electrode CM3 in order to prevent the third connection electrode CM3 from being damaged by an etchant used to etch the pixel electrode 210. The inorganic protective layer PVX′ may be formed of an inorganic material such as silicon nitride (SiNₓ) or silicon oxide (SiO₂).

The display panel 10 may be manufactured by stacking each layer on a support substrate MS and then cutting the layer along a cutting line CL as shown in FIG. 10. In this case, a plurality of grooves may be located between the cutting line and a display area DA, and at least one groove may also be located outside the cutting line CL. In this case, the cutting line CL may be formed between adjacent grooves, and the substrate 100 may be separated from a mother substrate (not shown). Next, the substrate 100 may be separated from the support substrate MS.

An end of the display panel 10 located on a first cutting line CL-1 may form the same plane. That is, side surfaces of layers located on the end of the display panel 10 located on the first cutting line CL-1 may form one plane. For example, a side surface of the substrate 100 where the first cutting line CL-1 is located and a side surface of at least one of the inorganic insulating layer IL, the first inorganic encapsulation layer 310, and the second inorganic encapsulation layer 330 may be flat and form the same plane.

In detail, in the above case, the first cutting line CL-1 may be located between adjacent grooves G. For example, the first cutting line CL-1 may be located on a protruding portion of the substrate 100 between the grooves G.

As described above, a protruding portion 103-1 of the second base layer 103 and the first edge inorganic layer EDL1 may be located on an end of the display panel 10 where the first cutting line CL-1 is located. In this case, the first edge inorganic layer EDL1 may include at least one of a second barrier layer (not shown), the buffer layer 111, the first gate insulating layer 112, the second gate insulating layer 113, the interlayer insulating layer 115, the inorganic layer PVX, the first inorganic encapsulation layer 310, and the second inorganic encapsulation layer 330. For convenience of explanation, the following will be described assuming that the first edge inorganic layer EDL1 includes the buffer layer 111, the first gate insulating layer 112, the second gate insulating layer 113, the interlayer insulating layer 115, the first inorganic encapsulation layer 310, and the second inorganic encapsulation layer 330.

In the above case, the groove G may prevent propagation of cracks in the substrate 100 to the display area DA when the substrate 100 is separated from the mother substrate along the first cutting line CL-1. Also, because the display panel 10 has this structure, the area of the peripheral area PA may be reduced. In addition, when the display panel 10 has the same size as that of an existing display panel, the display panel 10 may include the display area DA that is larger than that of the existing display panel.

FIG. 11B is a cross-sectional view schematically illustrating a part of the display panel, taken along line D-D′ of FIG. 10, according to another embodiment.

Referring to FIG. 11B, the display panel 10 may include the substrate 100, the inorganic insulating layer IL, the organic insulating layer OL, the bank layer 119, the first pixel electrode 210, the first emission layer 220, the counter electrode 230, the thin-film encapsulation layer 300, the dam unit DAM, the inorganic layer PVX, and the inorganic protective layer PVX′. The inorganic insulating layer IL may include the buffer layer 111, the first gate insulating layer 112, the second gate insulating layer 113, and the interlayer insulating layer 115. The organic insulating layer OL may include the first organic insulating layer OL1, the second organic insulating layer OL2, the third organic insulating layer OL3, and the fourth organic insulating layer OL4. The thin-film encapsulation layer 300 may include the first inorganic encapsulation layer 310, the organic encapsulation layer 320, and the second inorganic encapsulation layer 330. The dam unit DAM may include the first dam DAM1, the second dam DAM2, the third dam DAM3, and the fourth dam DAM4. In this case, the display panel 10 may include the substrate 100, the inorganic insulating layer IL, the organic insulating layer OL, the bank layer 119, the first pixel electrode 210, the first emission layer 220, the counter electrode 230, the thin-film encapsulation layer 300, the dam unit DAM, the inorganic layer PVX, and the inorganic protective layer PVX′. The buffer layer 111, the first gate insulating layer 112, the second gate insulating layer 113, and the interlayer insulating layer 115 of the inorganic insulating layer IL are the same as or similar to those described with reference to FIGS. 9 and 11A, and thus, a detailed description thereof will be omitted. A difference from FIG. 11A will be mainly described.

In the above case, a plurality of grooves may be located outside the display area DA when the display panel 10 is manufactured. In this case, the substrate 100 may be separated from a mother substrate (not shown) by forming the first cutting line CL-1 inside one of the plurality of grooves G. Next, the substrate 100 may be separated from a support substrate (not shown).

An edge groove 103-2 may be located on the first cutting line CL-1. In this case, the edge groove 103-2 may be formed by removing at least a part of the substrate 100. For example, the edge groove 103-2 may be formed by removing a part of the second base layer 103, and the edge groove 103-2 may be recessed downward from a top surface of the substrate 100.

The first cutting line CL-1 may be located inside one of the plurality of grooves G. When the mother substrate is cut along the first cutting line CL-1, only a part of the groove G where the first cutting line CL-1 is located may remain.

In this case, an end of the display panel 10 where the first cutting line CL-1 is located may be lower than a top surface of the substrate 100. That is, a thickness of a part of the second base layer 103 located on the end of the display panel 10 where the first cutting line CL-1 is located may be less than a thickness of other portions of the second base layer 103.

In the above case, on a side surface of the display panel 10 where the first cutting line CL-1 is located, a side surface of the first base layer 101, a side surface of the first barrier layer 102, and a side surface of a part of the second base layer 103 may be located, to form the same plane. In this case, a first edge inorganic layer as shown in FIG. 11A may not be located on the side surface of the display panel 10 where the first cutting line is located.

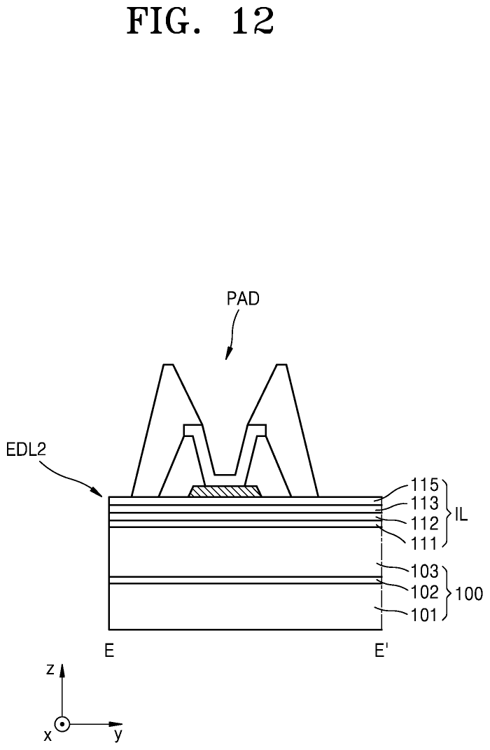

FIG. 12 is a cross-sectional view schematically illustrating a part of the display panel, taken along line E-E′ of FIG. 10, according to an embodiment.

Referring to FIG. 12, a terminal (not shown) connected to a terminal of an external flexible circuit board (not shown) may be provided in the terminal unit PAD. In this case, an end of the display panel 10 where the second cutting line CL-2 is located may be different from the display panel 10 of FIGS. 11A and 11B. For example, although not shown in FIG. 12, the groove G illustrated in FIGS. 11A and 11B may not be located in the end of the display panel 10 where the second cutting line CL-2 is located. In this case, the dam unit DAM may be located between the terminal unit PAD and a display area (not shown).

In the above case, the second edge inorganic layer EDL2 may be located on the substrate 100 on a portion of the second cutting line CL-2 located outside the terminal unit PAD. In this case, the second edge inorganic layer EDL2 may include at least one of a second barrier layer (not shown), the buffer layer 111, the first gate insulating layer 112, the second gate insulating layer 113, and the interlayer insulating layer 115. For convenience of explanation, the following will be described assuming that the second edge inorganic layer EDL2 includes the buffer layer 111, the first gate insulating layer 112, the second gate insulating layer 113, and the interlayer insulating layer 115.

In the above case, the second edge inorganic layer EDL2 may be different from the first edge inorganic layer EDL1 described with reference to FIG. 11A. That is, while the first edge inorganic layer EDL1 includes at least one of the inorganic layer PVX, the first inorganic encapsulation layer 310, and the second inorganic encapsulation layer 330, the second edge inorganic layer EDL2 may not include the inorganic layer PVX, the first inorganic encapsulation layer 310, and the second inorganic encapsulation layer 330. Also, although a separate first edge inorganic layer is not located on a side surface of the display panel 10 where the first cutting line CL-1 is located as shown in FIG. 11B, the second edge inorganic layer EDL2 may be located on the substrate 100 on a side surface of the display panel 10 where the second cutting line CL-2 is located as shown in FIG. 12. In this case, a groove described with reference to FIGS. 11A and 11B may not be located in a portion where the second edge inorganic layer EDL2 is located.

FIG. 13 is a cross-sectional view schematically illustrating a part of the display panel, taken along line D-D′ of FIG. 10, according to another embodiment.

Referring to FIG. 13, the display panel 10 may include the substrate 100, the inorganic insulating layer IL, the organic insulating layer OL, the bank layer 119, the first pixel electrode 210, the first emission layer 220, the counter electrode 230, the thin-film encapsulation layer 300, the dam unit DAM, the inorganic layer PVX, and the inorganic protective layer PVX′. The inorganic insulating layer IL may include the buffer layer 111, the first gate insulating layer 112, the second gate insulating layer 113, and the interlayer insulating layer 115. The organic insulating layer OL may include the first organic insulating layer OL1, the second organic insulating layer OL2, the third organic insulating layer OL3, and the fourth organic insulating layer OL4. The thin-film encapsulation layer 300 may include the first inorganic encapsulation layer 310, the organic encapsulation layer 320, and the second inorganic encapsulation layer 330. The dam unit DAM may include the first dam DAM1, the second dam DAM2, the third dam DAM3, and the fourth dam DAM4. In this case, the display panel 10 may include the substrate 100, the inorganic insulating layer IL, the organic insulating layer OL, the bank layer 119, the first pixel electrode 210, the first emission layer 220, the counter electrode 230, the thin-film encapsulation layer 300, the dam unit DAM, the inorganic layer PVX, and the inorganic protective layer PVX′. The buffer layer 111, the first gate insulating layer 112, the second gate insulating layer 113, and the interlayer insulating layer 115 of the inorganic insulating layer IL are the same as or similar to those described with reference to FIGS. 9 and 11A, and thus, a detailed description thereof will be omitted. Hereinafter, a difference from the display panel of FIG. 11A will be mainly described.

A first side surface 101-EG of the first base layer 101 located and a second side surface 103-EG of the second base layer 103 at an end of the display panel 10 may be flat. In this case, the first side surface 101-EG of the first base layer 101 and the second side surface 103-EG of the second base layer 103 may be located on the same plane. A third end 102-EG of the first barrier layer 102 located between the first base layer 101 and the second base layer 103 may protrude from at least one of the first side surface 101-EG of the first base layer 101 and the second side surface 103-EG of the second base layer 103 away from a display area (not shown).

Also, at least one of a second barrier layer (not shown), the buffer layer 111, the first gate insulating layer 112, the second gate insulating layer 113, the interlayer insulating layer 115, and the inorganic layer PVX located on the second base layer 103 may protrude from the second side surface 103-EG. In this case, when the second barrier layer is located on the second base layer 103, the second barrier layer (not shown) may protrude from the second side surface 103-EG of the second base layer 103, like the first barrier layer 102. Also, the buffer layer 111, the first gate insulating layer 112, the second gate insulating layer 113, and the interlayer insulating layer 115 may also protrude from the second side surface 103-EG of the second base layer 103, like the first barrier layer 102.

For convenience of explanation, the following will be described assuming that a fourth end PVX-EG of the inorganic layer PVX protrudes from the second side surface 103-EG of the second base layer 103.

In the above case, the inorganic layer PVX may extend from the inside of the fourth dam DAM4 and may be located on the second base layer 103. In this case, the fourth end PVX-EG of the inorganic layer PVX may protrude from the second side surface 103-EG of the second base layer 103 as described above.

In the above case, at least one of the first inorganic encapsulation layer 310 and the second inorganic encapsulation layer 330 may surround a side surface of the substrate 100. For convenience of explanation, the following will be described assuming that the first inorganic encapsulation layer 310 and the second inorganic encapsulation layer 330 surround a side surface of the substrate 100.

The first inorganic encapsulation layer 310 and the second inorganic encapsulation layer 330 may extend from the dam unit DAM, to cover the fourth end PVX-EG of the inorganic layer PVX, the second side surface 103-EG of the second base layer 103, the third end 102-EG of the first barrier layer 102, and the first side surface 101-EG of the first base layer 101. In this case, a portion of the first inorganic encapsulation layer 310 and a portion of the second inorganic encapsulation layer 330 located on a side surface of the display panel 10 may be uneven. The portion of the first inorganic encapsulation layer 310 and the portion of the second inorganic encapsulation layer 330 may correspond to a portion of the first cutting line shown in FIGS. 11A and 11B.

In the above case, although not, it may have a different shape from an edge of a display panel located on a portion of the second cutting line CL-2 where the terminal unit is located. In this case, the edge of the display panel where the second cutting line is located may be as shown in FIG. 12.

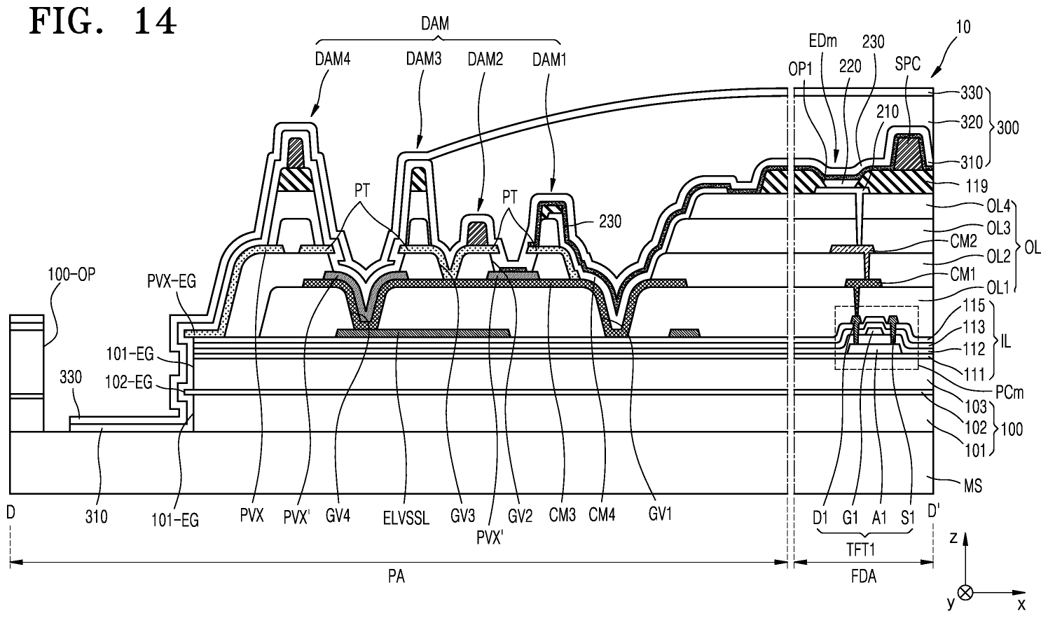

FIG. 14 is a cross-sectional view schematically illustrating part of a method of manufacturing the display panel of FIG. 13.

Referring to FIG. 14, in the display panel 10, the dam unit DAM may be formed, and then, a substrate opening 100-OP may be formed by removing a part of the substrate 100 by using dry etching or the like. In this case, the fourth end PVX-EG of the inorganic layer PVX may protrude from the second side surface 103-EG of the second base layer 103. Also, next, the first inorganic encapsulation layer 310, the organic encapsulation layer 320, and the second inorganic encapsulation layer 330 may be sequentially formed. In this case, the first inorganic encapsulation layer 310 and the second inorganic encapsulation layer 330 may be located on an end of the inorganic insulating layer IL, the fourth end PVX-EG of the inorganic layer PVX, the second side surface 103-EG of the second base layer 103, the third end 102-EG of the first barrier layer 102, and the first side surface 101-EG of the first base layer 101, and then may extend into the substrate opening 100-OP. In this case, an outer surface of the support substrate MS may be exposed through the substrate opening 100-OP, and the first inorganic encapsulation layer 310 and the second inorganic encapsulation layer 330 may be located on the outer surface of the support substrate MS.

After the above process is completed, the support substrate MS may be separated from the substrate 100. In this case, the first inorganic encapsulation layer 310 and the second inorganic encapsulation layer 330 located on the support substrate MS may be removed along with the support substrate MS, and the first inorganic encapsulation layer 310 and the second inorganic encapsulation layer 330 may be located as shown in FIG. 13.

In the above case, the first inorganic encapsulation layer 310 and the second inorganic encapsulation layer 330 located on a side surface of the substrate 100 may prevent penetration of external air or moisture into the display area.

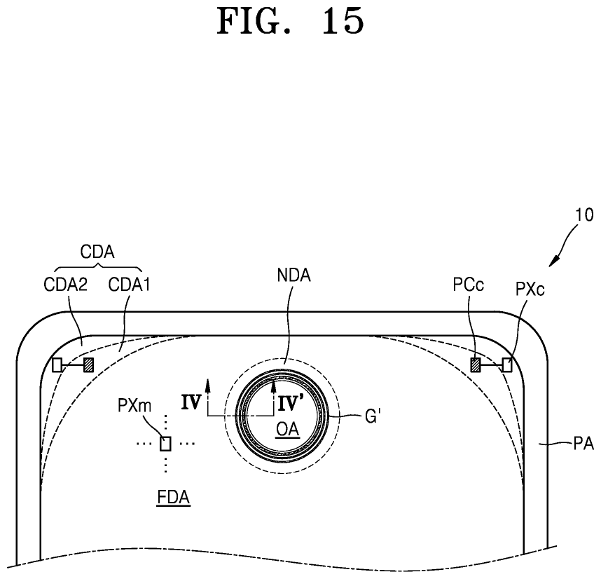

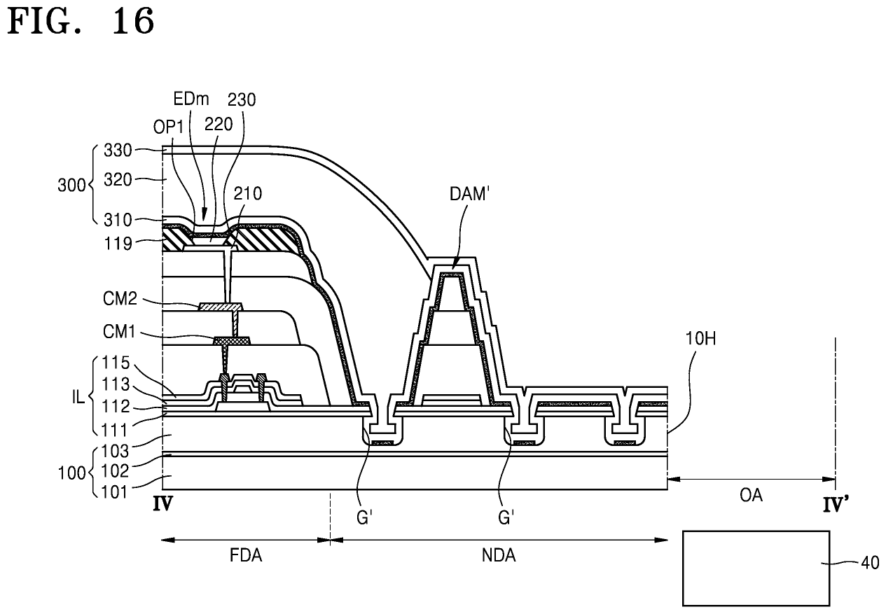

FIG. 15 is a schematic plan view illustrating a state where a part of a display panel is unfolded, according to another embodiment. FIG. 16 is a schematic cross-sectional view taken along line E-E′ of FIG. 15.

Referring to FIGS. 15 and 16, the display panel 10 may include an opening area OA located inside the front display area FDA and a non-display area NDA surrounding the opening area OA.

The opening area OA may have any of various planar shapes such as a circular shape, an elliptical shape, a polygonal shape such as a quadrangular shape, a star shape, or a diamond shape. A position of the opening area OA may also be changed in various ways. For example, the opening area OA may be located in the upper center of the front display area FDA as shown in FIG. 15, or unlike this, the opening area OA may be located in right center or left center of the front display area FDA.

As shown in FIG. 16, a component 40 that is an electronic element may be located under the display panel 10 to correspond to the opening area OA. The component 40 that is a camera using infrared light or visible light may include an image pickup device. Alternatively, the component 40 may be a solar cell, a flash, an illuminance sensor, a proximity sensor, or an iris sensor. Alternatively, the component 40 may have a function of receiving sound.

Referring back to FIG. 15, the non-display area NDA may surround the opening area OA. The non-display area NDA is an area where a display element such as a light-emitting diode for emitting light is not located, and signal lines for applying signals to the main pixels PXm located around the opening area OA may pass through the non-display area NDA or an additional groove G′ may be located in the non-display area NDA.

Although three additional grooves G′ are located in the non-display area NDA in FIG. 15, the disclosure is not limited thereto. In another embodiment, one, two, or four or more grooves G′ may be located in the non-display area NDA.

The additional grooves G′ may have a ring shape entirely surrounding the opening area OA in a first non-display area NDA1. A diameter of each of the additional grooves G′ may be greater than a diameter of the opening area OA. In a plan view, the additional grooves G′ surrounding the opening area OA may be spaced apart from each other by a certain interval.

Referring to FIG. 16, the display panel 10 may include a first opening 10H corresponding to the opening area OA. The main light-emitting element EDm may be located in the front display area FDA, and the counter electrode 230 of the main light-emitting element EDm may extend to the non-display area NDA.

A plurality of additional grooves G′ may be located in the non-display area NDA. The additional groove G′ may be formed by spatially connecting a recess obtained by removing a part of the second base layer 103 to a hole passing through the inorganic insulating layer IL.

The inorganic insulating layer IL may include a protruding tip protruding toward the additional groove G′. An organic layer (not shown) and the counter electrode 230 that may be included in the main light-emitting element EDm may be disconnected around the additional groove G′ by the protruding tip of the inorganic insulating layer IL.

The first inorganic encapsulation layer 310 of the thin-film encapsulation layer 300 has better step coverage than the counter electrode 230. Accordingly, the first inorganic encapsulation layer 310 may be continuously formed without being disconnected in the additional groove G′.

An additional dam DAM′ may be located in the non-display area NDA, and the additional dam DAM′ may block the flow of the organic encapsulation layer 320. The first inorganic encapsulation layer 310 and the second inorganic encapsulation layer 330 may contact each other between the additional dam DAM′ and the opening area OA.

The additional groove G′ formed in the non-display area NDA may be formed simultaneously with the plurality of grooves G described with reference to FIG. 11A and FIG. 11B.

A display panel and a display apparatus according to embodiments may increase a display area. Also, a display panel and a display apparatus according to embodiments may reduce a peripheral area. Also, a display panel and a display apparatus according to embodiments may block external moisture and air.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by one of ordinary skill in the art that various changes in form and details may be made therein without departing from the spirit and scope as defined by the following claims.

What is claimed is:

1. A display panel comprising:
a substrate comprising a display area and a peripheral area around the display area;
a display element located in the display area;
a thin-film encapsulation layer covering the display area, and comprising a first inorganic encapsulation layer, an organic encapsulation layer, and a second inorganic encapsulation layer; and
a plurality of grooves located in the peripheral area to be adjacent to an end of the substrate,
wherein the end of the substrate is recessed away from the display element, and a side surface of the end of the substrate is one plane.

2. The display panel of claim 1, further comprising:
an inorganic insulating layer located between the substrate and the display element; and
an inorganic layer located on the substrate in the peripheral area.

3. The display panel of claim 2, wherein at least one of a barrier layer of the substrate, the inorganic insulating layer, the organic layer, the first inorganic encapsulation layer, and the second inorganic encapsulation layer is located between the plurality of grooves.

4. The display panel of claim 1, wherein the substrate comprises:
a first base layer;
a second base layer located between the first base layer and the display element; and
a barrier layer located between the first base layer and the second base layer.

5. The display panel of claim 4, wherein each of the plurality of grooves is located in the second base layer.

6. The display panel of claim 1, further comprising:
a terminal unit located on the substrate; and
an edge inorganic layer located on an end portion of the substrate adjacent to the terminal unit,
wherein a side surface of the edge inorganic layer located on the end portion of the substrate adjacent to the terminal unit, and a side surface of the substrate form one plane.

7. The display panel of claim 6, further comprising an inorganic insulating layer located between the substrate and the display element,
wherein the edge inorganic layer comprises at least one of a barrier layer of the substrate, the inorganic insulating layer, the inorganic layer, the first inorganic encapsulation layer, and the second inorganic encapsulation layer.

8. A display panel comprising:
a substrate comprising a display area and a peripheral area around the display area;
a display element located in the display area;
a thin-film encapsulation layer covering the display area, and comprising a first inorganic encapsulation layer, an organic encapsulation layer, and a second inorganic encapsulation layer;
a plurality of grooves located in the peripheral area to be adjacent to an end of the substrate;
a terminal unit located on the substrate; and
a first edge inorganic layer located on a protruding portion of the substrate located outside the plurality of grooves,
wherein, in a plan view, a portion of the first edge inorganic layer close to the terminal unit is open, and
a side surface of the end of the substrate and a side surface of an end of the first edge inorganic layer are on a same plane.

9. The display panel of claim 8, further comprising:
an inorganic insulating layer located between the substrate and the display element; and
an inorganic layer located on the substrate between the first edge inorganic layer and the inorganic insulating layer.

10. The display panel of claim 9, wherein the first edge inorganic layer comprises at least one of a barrier layer of the substrate, the inorganic insulating layer, the inorganic layer, the first inorganic encapsulation layer, and the second inorganic encapsulation layer.

11. The display panel of claim 8, wherein the substrate comprises:
a first base layer;
a second base layer located between the first base layer and the display element; and
a barrier layer located between the first base layer and the second base layer.

12. The display panel of claim 11, wherein each of the plurality of grooves is located on the second base layer.

13. The display panel of claim 8, further comprising a second edge inorganic layer located on an end portion of the substrate adjacent to the terminal unit,
wherein a side surface of the second edge inorganic layer located on the end portion of the substrate adjacent to the terminal unit and a side surface of the substrate are on a same plane.

14. The display panel of claim 13, further comprising an inorganic insulating layer located between the substrate and the display element,
wherein the second edge inorganic layer comprises at least one of a part of the substrate and the inorganic insulating layer.

15. A display panel comprising:
a substrate comprising a display area and a peripheral area around the display area;
a display element located in the display area; and
a thin-film encapsulation layer covering the display area, and comprising a first inorganic encapsulation layer, an organic encapsulation layer, and a second inorganic encapsulation layer,
wherein the substrate comprises:
a first base layer;
a second base layer located between the first base layer and the display element; and
a first barrier layer located between the first base layer and the second base layer,
wherein an end of the first barrier layer protrudes from at least one of a side surface of the first base layer and a side surface of the second base layer.

16. The display panel of claim 15, wherein the side surface of the first base layer and the side surface of the second base layer are on a same plane.

17. The display panel of claim 15, wherein at least one of the first inorganic encapsulation layer and the second inorganic encapsulation layer surrounds a side surface of the substrate.

18. The display panel of claim 15, further comprising:
a terminal unit located on the substrate; and
an edge inorganic layer located on an end portion of the substrate adjacent to the terminal unit,
wherein a side surface of the edge inorganic layer located on the end portion of the substrate adjacent to the terminal unit and a side surface of the substrate form one plane.

19. The display panel of claim 18, further comprising an inorganic insulating layer located between the substrate and the display element,
wherein the edge inorganic layer comprises at least one of a part of the substrate and the inorganic insulating layer.

20. The display panel of claim 15, further comprising an inorganic layer located between an end of the substrate and the display element,
wherein an end of the inorganic layer located on the end of the substrate protrudes from at least one of a side surface of the first base layer and a side surface of the second base layer.
